(19) United States
(12) Patent Application Publication
(10) Pub. No.: US 2013/0342885 A1
(43) Pub. Date: Dec. 26, 2013

(54) DISPERSION COMPENSATION OPTICAL APPARATUS AND SEMICONDUCTOR LASER APPARATUS ASSEMBLY

(71) Applicant: Sony Corporation, Tokyo (JP)

(72) Inventors: Shunsuke Kono, Kanagawa (JP); Masaru Kuramoto, Kanagawa (JP); Kimihiro Saito, Kanagawa (JP); Seiji Kobayashi, Kanagawa (JP)

(21) Appl. No.: 13/916,249

(22) Filed: Jun. 12, 2013

(30) Foreign Application Priority Data
Jun. 26, 2012 (JP) 2012-143351

(51) Int. Cl. G02B 5/32; H01S 5/00

(52) U.S. Cl. CPC G02B 5/32; H01S 5/005
USPC 359/15; 359/337.5

(57) ABSTRACT

Disclosed is a dispersion compensation optical apparatus including a first transmission type volume hologram diffraction grating and a second transmission type volume hologram diffraction grating. The first and second transmission type volume hologram diffraction gratings are arranged facing each other. A sum of an incident angle of laser light and an emitting angle of first-order diffracted light is 90° in each of the first and second transmission type volume hologram diffraction gratings.

### CROSS REFERENCES TO RELATED APPLICATIONS

The present application claims priority to Japanese Priority Patent Application JP 2012-143351 filed in the Japan Patent Office on Jun. 26, 2012, the entire content of which is hereby incorporated by reference.

### BACKGROUND

The present disclosure relates to a dispersion compensation optical apparatus and a semiconductor laser apparatus assembly that incorporates the dispersion compensation optical apparatus.

Ultrashort pulse laser apparatuses as represented by titanium/sapphire laser apparatuses driven based on a mode synchronization method generate a laser light pulse having a time width of femto seconds to pico seconds. Due to its high peak power, a laser light pulse emitted from an ultrashort pulse laser apparatus causes, when applied to a substance, physical phenomena different from those of a normal continuous oscillation laser apparatus. Most of the physical phenomena have been known as non-linear optical phenomena and widely used in recent years for the processing of biological microscopes and fine structures or the like.

The laser light pulse emitted from the ultrashort pulse laser apparatus is often amplified by an amplifier to obtain the high peak power. Here, in order to obtain large pulse energy with the amplifier, there has been known a method (called “chirped pulse amplification”) in which the pulse time width of laser light incident on the amplifier is extended and then compressed again after the amplification. Further, a pulse compression and extension unit (also called a “dispersion compensation optical apparatus”) based on the wavelength dispersion of ultrashort pulse laser light is used to execute the chirped pulse amplification.

In particular, a semiconductor laser device using a semiconductor gain medium has a lifespan of about nano seconds, which is shorter than a solid medium laser apparatus such as a titanium/sapphire laser apparatus and a YAG laser apparatus. Therefore, if the pulse of the laser light of about pico seconds generated by a mode synchronous semiconductor laser device is directly amplified by an amplifier, a carrier number for amplification is temporally limited and amplification efficiency is reduced compared with a case in which continuous light is amplified. Accordingly, a dispersion compensation optical apparatus is desired to realize a small semiconductor laser apparatus assembly that generates an ultrashort laser light pulse having high peak power.

As shown in FIG. 20, the dispersion compensation optical apparatus generally includes two engraved diffraction gratings. However, high diffraction efficiency is not easily secured with the engraved diffraction gratings, and the throughput of the dispersion compensation optical apparatus is low. For example, the efficiency of an available engraved diffraction gratings used at an incident wavelength of a 400 nm band is about 75%. Because an engraved interval becomes small with a reduction in the incident wavelength, the manufacturing of the engraved diffraction gratings becomes gradually difficult and the diffraction efficiency thereof is reduced. Further, in the dispersion compensation optical apparatus including the two engraved diffraction gratings, the throughput is reduced down to (75%)²≈56%. In addition, high-order diffracted light is generated depending on the interval between the gratings in the engraved diffraction gratings, and thus conditions for obtaining first-order diffracted light having high diffraction efficiency are limited. Moreover, in the engraved diffraction gratings, the diffraction angle depends on an engraved number and a wavelength. Therefore, the degree of flexibility in the optical arrangement of the dispersion compensation optical apparatus is low.

### SUMMARY

From the Non-Patent Literature “Femtosecond laser pulse compression using volume phase transmission holograms” by Tsung-Yuan Yang, et al. Applied Optics, 1 Jul. 1985, Vol. 24, No. 13a, there has been known technology for constituting a dispersion compensation optical apparatus with two transmission type volume hologram diffraction gratings instead of such engraved diffraction gratings. This Non-Patent Literature reports the verification of the principle of pulse compression using the transmission type volume hologram diffraction gratings. However, it does not disclose an optimal configuration for the size reduction of the dispersion compensation optical apparatus.

Accordingly, it is desirable to provide a dispersion compensation optical apparatus capable of reducing its size and a semiconductor laser apparatus assembly that incorporates the dispersion compensation optical apparatus.

According to a first mode of the present disclosure, there is provided a dispersion compensation optical apparatus including a first transmission type volume hologram diffraction grating and a second transmission type volume hologram diffraction grating. The first and second transmission type volume hologram diffraction gratings are arranged facing each other, and a sum of an incident angle φᵢₙ of laser light and an emitting angle φₒᵤₜ of first-order diffracted light is 90° in each of the first and second transmission type volume hologram diffraction gratings. In other words, the relational expression φᵢₙ+φₒᵤₜ=90° is established. Here, the incident angle and the emitting angle are angles formed with respect to the normal lines of the laser light incident faces of the transmission type volume hologram diffraction gratings. The same applies to the following description.

In addition, according to a second mode of the present disclosure, there is provided a dispersion compensation optical apparatus including a first transmission type volume hologram diffraction grating and a second transmission type volume hologram diffraction grating. The first and second transmission type volume hologram diffraction gratings are arranged facing each other, and an incident angle φᵢₙ of laser light and an emitting angle φₒᵤₜ of first-order diffracted light are substantially equal in each of the first and second transmission type volume hologram diffraction gratings. Specifically, the relational expression 0.95≦φᵢₙ/φₒᵤₜ≦1.00 is established.

Moreover, according to a third mode of the present disclosure, there is provided a dispersion compensation optical apparatus including a transmission type volume hologram diffraction grating and a reflection mirror. A sum of an incident angle of laser light and an emitting angle φₒᵤₜ of first-order diffracted light is 90° or the incident angle of the laser light and the emitting angle φₒᵤₜ of the first-order diffracted light are substantially equal in the transmission type volume hologram diffraction grating. The laser light emitted from a semiconductor laser device is incident on the transmission type volume hologram diffraction grating to be diffracted and emitted as the first-order diffracted light to collide with the reflection mirror. The first-order diffracted light reflected by the reflection mirror is incident on the transmission type volume hologram diffraction grating again to be diffracted and emitted to an outside of a system.

Furthermore, a semiconductor laser apparatus assembly according to the first mode of the present disclosure includes a mode synchronous semiconductor laser device and the dispersion compensation optical apparatus according to the first mode of the present disclosure on which the laser light emitted from the mode synchronous semiconductor laser device is incident.

Furthermore, a semiconductor laser apparatus assembly according to the second mode of the present disclosure includes a mode synchronous semiconductor laser device, a first dispersion compensation optical apparatus on which laser light emitted from the mode synchronous semiconductor laser device is incident, a semiconductor light amplifier on which the laser light emitted from the first dispersion compensation optical apparatus is incident, and a second dispersion compensation optical apparatus on which the laser light emitted from the semiconductor light amplifier is incident.

In the dispersion compensation optical apparatus according to the first mode of the present disclosure, the sum of the incident angle of the laser light and the emitting angle φₒᵤₜ of first-order diffracted light is 90° in each of the transmission type volume hologram diffraction gratings. In the dispersion compensation optical apparatus according to the second mode of the present disclosure, the incident angle of the laser light and the emitting angle φₒᵤₜ of the first-order diffracted light are substantially equal in each of the transmission type volume hologram diffraction gratings. In the dispersion compensation optical apparatus according to the third mode of the present disclosure, the transmission type volume hologram diffraction grating and the reflection mirror are provided. Accordingly, it is possible to provide the small dispersion compensation optical apparatus that achieves a high throughput with high diffraction efficiency and arbitrarily set a diffraction angle. As a result, an increase in the degree of flexibility in the optical design of the dispersion compensation optical apparatus is allowed. In addition, the adjustment of the group velocity dispersion value (dispersion compensation amount) of the dispersion compensation optical apparatus is facilitated. As a result, an increase in the degree of flexibility in the arrangement of optical components constituting the dispersion compensation optical apparatus is allowed.

Additional features and advantages are described herein, and will be apparent from the following Detailed Description and the figures.

### BRIEF DESCRIPTION OF THE FIGURES

FIG. 1 is a conceptual diagram of the semiconductor laser apparatus assembly of a first embodiment;

FIGS. 2A and 2B are a schematic partial cross-sectional diagram of a transmission type volume hologram diffraction grating and a diagram showing the outline of a chirp phenomenon in the semiconductor laser apparatus assembly of the first embodiment, respectively;

FIGS. 3A and 3B are conceptual diagrams of the dispersion compensation optical apparatuses of second and third embodiments, respectively;

FIGS. 4A and 4B are conceptual diagrams of the dispersion compensation optical apparatus of a fourth embodiment and a modification thereof, respectively;

FIGS. 5A and 5B are a conceptual diagram of the dispersion compensation optical apparatus for describing problems possibly caused in the dispersion compensation optical apparatus and a conceptual diagram of the dispersion compensation optical apparatus of a fifth embodiment, respectively;

FIG. 6 is a conceptual diagram of the semiconductor laser apparatus assembly of a sixth embodiment;

FIGS. 7A and 7B are conceptual diagrams of the dispersion compensation optical apparatus of a seventh embodiment;

FIGS. 8A and 8B are conceptual diagrams of the wavelength selection unit of the dispersion compensation optical apparatus of an eighth embodiment;

FIG. 9 is a schematic end face diagram along a direction in which the resonator of the mode synchronous semiconductor laser device of the first embodiment extends;

FIG. 10 is a schematic cross-sectional diagram along a direction perpendicular to the direction in which the resonator of the mode synchronous semiconductor laser device of the first embodiment extends;

FIG. 11 is a schematic end face diagram along a direction in which the resonator of a modification of the mode synchronous semiconductor laser device of the first embodiment extends;

FIG. 12 is a schematic end face diagram along a direction in which the resonator of another modification of the mode synchronous semiconductor laser device of the first embodiment extends;

FIG. 13 is a schematic diagram of the ridge stripe structure of still another modification of the mode synchronous semiconductor laser device of the first embodiment as seen from the above;

FIG. 14 is a graph showing the dependence dφₒᵤₜ/dλ of spatial dispersion with respect to the emitting angle (diffraction angle) φₒᵤₜ of first-order diffracted light in the transmission type volume hologram diffraction grating;

FIG. 15 is a graph showing the result of calculating the term of sin² depending on a refractive index modulation degree Δn in formula (12);

FIG. 16 is a graph showing a change in diffraction efficiency η when the spectrum width of incident light is changed in a state in which the thickness L of a diffraction grating member, the refractive index modulation degree Δn, and a wavelength λ constituting the dispersion compensation optical apparatus are fixed;

FIGS. 17A and 17B are schematic partial cross-sectional diagrams of a substrate or the like for describing a method for manufacturing the mode synchronous semiconductor laser device of the first embodiment;

FIGS. 18A and 18B are schematic partial cross-sectional diagrams of the substrate or the like for describing the method for manufacturing the mode synchronous semiconductor laser device of the first embodiment in succession to FIG. 17B;

FIG. 19 is a schematic partial end face diagram of the substrate or the like for describing the method for manufacturing the mode synchronous semiconductor laser device of the first embodiment in succession to FIG. 18B; and

FIG. 20 is a conceptual diagram of a typical dispersion compensation optical apparatus including two engraved diffraction gratings.

### DETAILED DESCRIPTION

Hereinafter, referring to the drawings, a description will be given of the present disclosure based on embodiments. However, the present disclosure is not limited to the embodiments, and various numerical values and materials in the embodiments are given for exemplary purposes. Note that the description will be given in the following order.

1. Description of the various aspects of dispersion compensation optical apparatuses according to first to third modes of the present disclosure and semiconductor laser apparatus assemblies according to the first and second modes of the present disclosure

2. First Embodiment (the dispersion compensation optical apparatus according to the first mode of the present disclosure and the semiconductor laser apparatus assemblies according to the first and second modes of the present disclosure)

3. Second Embodiment (modification of the first embodiment)

4. Third Embodiment (another modification of the first embodiment)

5. Fourth Embodiment (still another modification of the first embodiment)

6. Fifth Embodiment (modification of the first, second, and fourth embodiments)

7. Sixth Embodiment (the dispersion compensation optical apparatus according to the second mode of the present disclosure)

8. Seventh Embodiment (the dispersion compensation optical apparatus according to the third mode of the present disclosure)

9. Eighth Embodiment (modification of the first to seventh embodiments)

10. Ninth Embodiment (modification of the first to eighth embodiments)

(Description of the Various Aspects of Dispersion Compensation Optical Apparatuses According to First to Third Modes of the Present Disclosure and Semiconductor Laser Apparatus Assemblies According to the First and Second Embodiments of the Present Disclosure)

The dispersion compensation optical apparatus according to the first or second mode of the present disclosure and the dispersion compensation optical apparatus according to the first or second mode of the present disclosure of the semiconductor laser apparatus assembly according to the first mode of the present disclosure are collectively called the “dispersion compensation optical apparatuses or the like of the present disclosure” as occasion demands.

In the dispersion compensation optical apparatus according to the first mode of the present disclosure, the emitting angle φₒᵤₜ of first-order diffracted light is desirably larger than the incident angle of laser light in a first transmission type volume hologram diffraction grating on which the laser light emitted from a semiconductor laser device is incident from the viewpoint of increasing angular dispersion with the transmission type volume hologram diffraction grating. In this case, in a second transmission type volume hologram diffraction grating on which the first-order diffracted light emitted from the first transmission type volume hologram diffraction grating is incident, the emitting angle φₒᵤₜ of the first-order diffracted light may be smaller than the incident angle φᵢₙ of the laser light. Note that the incident angle of the laser light in the first transmission type volume hologram diffraction grating and the emitting angle (diffraction angle) φₒᵤₜ of the first-order diffracted light in the second transmission type volume hologram diffraction grating are desirably equal and that the emitting angle (diffraction angle) φₒᵤₜ of the first-order diffracted light in the first transmission type volume hologram diffraction grating and the incident angle φᵢₙ of the first-order diffracted light in the second transmission type volume hologram diffraction grating are desirably equal. The same applies to the dispersion compensation optical apparatuses or the like of the present disclosure (A) to (E), which will be described later.

In addition, in the dispersion compensation optical apparatus according to the second mode of the present disclosure, the sum of the incident angle φᵢₙ of the laser light and the emitting angle φₒᵤₜ of the first-order diffracted light is desirably 90° from the viewpoint of facilitating the adjustment of a group velocity dispersion value (dispersion compensation amount) in the dispersion compensation optical apparatus.

Further, in the dispersion compensation optical apparatus or the like of the present disclosure including the above desired configuration, the laser light may be incident on the first transmission type volume hologram diffraction grating and emitted as the first-order diffracted light. Moreover, the laser light may be incident on the second transmission type volume hologram diffraction grating to be diffracted and emitted as the first-order diffracted light to the outside of a system. The above form is called the “dispersion compensation optical apparatus or the like of the present disclosure (A)” for the sake of convenience. The laser light incident on the first transmission type volume hologram diffraction grating and the laser light emitted from the second transmission type volume hologram diffraction grating are desirably nearly parallel to each other (i.e., the laser light emitted from the first transmission type volume hologram diffraction grating is desirably parallel such that it is allowed to be incident on the second transmission type volume hologram diffraction grating) from the viewpoint of facilitating the arrangement and insertion of the dispersion compensation optical apparatus in an existing optical system. The same applies to the dispersion compensation optical apparatuses or the like of the present disclosure (B), (C), and (D), which will be described later.

In the dispersion compensation optical apparatus or the like of the present disclosure (A), first and second reflection mirrors parallel to each other may be further provided, and the laser light emitted from the second transmission type volume hologram diffraction grating may collide with the first reflection mirror to be reflected and then collide with the second reflection mirror to be reflected. The above form is called the “dispersion compensation optical apparatus or the like of the present disclosure (B)” for the sake of convenience. Moreover, the laser light reflected by the second reflection mirror may be nearly positioned on the extended line of the laser light incident on the first transmission type volume hologram diffraction grating, or the laser light incident on the first transmission type volume hologram diffraction grating and the laser light emitted from the second transmission type volume hologram diffraction grating may be parallel to each other. Thus, the arrangement and insertion of the dispersion compensation optical apparatus in an existing optical system is facilitated. The dispersion compensation optical apparatus or the like of the present disclosure (B) is a single path type dispersion compensation optical apparatus. Here, the expression “the laser light reflected by the second reflection mirror may be nearly positioned” indicates that the center of the second reflection mirror is positioned on the extended line of the angle at which the wavelength center of the spectrum of the pulse of the laser light incident on the first transmission type volume hologram diffraction grating is diffracted.

In addition, in the dispersion compensation optical apparatus or the like of the present disclosure (A), the first and second reflection mirrors may be further provided, and the laser light emitted from the first transmission type volume hologram diffraction grating may collide with the first reflection mirror to be reflected, collide with the second reflection mirror to be reflected, and be incident on the second transmission type volume hologram diffraction grating. The above form is called the “dispersion compensation optical apparatus or the like of the present disclosure (C)” for the sake of convenience. The dispersion compensation optical apparatus or the like of the present disclosure (C) is a single path type dispersion compensation optical apparatus. Note that a condensing unit (lens) is desirably provided between the first transmission type volume hologram diffraction grating and the first reflection mirror and that a condensing unit (lens) is desirably provided between the second reflection mirror and the second transmission type volume hologram diffraction grating from the viewpoint of adjusting a group velocity dispersion value (dispersion compensation amount).

In addition, in the dispersion compensation optical apparatus or the like of the present disclosure including the above desired configuration, the first transmission type volume hologram diffraction grating may be provided on a first face of a substrate, and the second transmission type volume hologram diffraction grating may be provided on a second face of the substrate, the second face facing the first face. The above form is called the “dispersion compensation optical apparatus of the like of the present disclosure (D)” for the sake of convenience. The dispersion compensation optical apparatus or the like of the present disclosure (D) is a single path type dispersion compensation optical apparatus. Examples of the substrate may include glasses including optical glasses such as quartz glass and BK7 and plastic materials (e.g., PMMA (polymethyl methacrylate), polycarbonate resins, acrylic-based resins, amorphous polypropylene-based resins, styrene-based resins containing AS resins).

In addition, in the dispersion compensation optical apparatus or the like of the present disclosure including the above desired configuration, the reflection mirror may be further provided, and the laser light may be incident on the first transmission type volume hologram diffraction grating to be diffracted and emitted as the first-order diffracted light. Moreover, the laser light may be incident on the second transmission type volume hologram diffraction grating to be diffracted, emitted as the first-order diffracted light, and collide with the reflection mirror. The laser light reflected by the reflection mirror may be incident on the second transmission type volume hologram diffraction grating again to be diffracted and emitted as the first-order diffracted light. Moreover, the laser light may be incident on the first transmission type volume hologram diffraction grating again to be diffracted and emitted to the outside of a system. The above form is called the “dispersion compensation optical apparatus or the like of the present disclosure (E)” for the sake of convenience. The dispersion compensation optical apparatus or the like of the present disclosure (E) is a double path type dispersion compensation optical apparatus.

In each of the dispersion compensation optical apparatuses or the like of the present disclosure including the various desired configurations and forms described above, the group velocity dispersion value (dispersion compensation amount) may be changed with a change in the distance (including the optical distance) between the two transmission type volume hologram diffraction gratings. Here, in the dispersion compensation optical apparatus or the like of the present disclosure (D), it is only desired to change the thickness of the substrate in order to change the distance between the two transmission type volume hologram diffraction gratings. However, the group velocity dispersion value (dispersion compensation amount) is actually a fixed value. In addition, in the dispersion compensation optical apparatus or the like of the present disclosure (E), the distance between the second transmission type volume hologram diffraction grating and the reflection mirror may be changed. Moreover, in the dispersion compensation optical apparatus according to the third mode of the present disclosure, the group velocity dispersion value (dispersion compensation amount) may be changed with a change in the distance between the transmission type volume hologram diffraction grating and the reflection mirror. In order to change the distance, it is only desired to use a known moving unit. The desired group velocity dispersion value depends on the characteristics of the pulse of the laser light emitted from a mode synchronous semiconductor laser assembly. Further, the characteristics of the pulse of the laser light are totally determined based on the configuration and structure of a mode synchronous semiconductor laser device, the configuration, structure, and driving method (e.g., the amount of current applied to a carrier implantation region (gain region), reverse bias voltage applied to a saturable absorption region (carrier non-implantation region), driving temperature) of a semiconductor laser apparatus assembly, or the like, and possibly cause both an up-chirp phenomenon (in which a wavelength changes from a long wave to a short wave (i.e., an increase in frequency) within the duration time of the pulse) and a down-chirp phenomenon (in which a wavelength changes from a short wave to a long wave (i.e., a decrease in frequency) within the duration time of the pulse) based on the group velocity dispersion value (dispersion compensation amount). Note that no chirp indicates a phenomenon in which the wavelength does not change within the duration time of the pulse (phenomenon in which the frequency does not change). Further, the pulse time width of the laser light may be extended/compressed by the appropriate selection of the value of the group velocity dispersion value of the dispersion compensation optical apparatus. Specifically, if the value of the group velocity dispersion value is set to be positive or negative with respect to the laser light pulse indicating the up-chirp phenomenon, it is possible to extend/compress the pulse time width of the laser light. In addition, if the value of the group velocity dispersion value is set to be positive or negative with respect to the laser light pulse indicating the down-chirp phenomenon, it is possible to compress/extend the pulse time width of the laser light. In the first-order diffracted light diffracted and emitted by the transmission type volume hologram diffraction grating, the light path length of a long wavelength component is different from that of a short wavelength component. Further, if the light path of the long wavelength component is longer than that of the short wavelength component, negative group velocity dispersion is formed. In other words, the group velocity dispersion value is set to be negative. On the other hand, if the light path of the long wavelength component is shorter than that of the short wavelength component, positive group velocity dispersion is formed. In other words, the group velocity dispersion value is set to be positive. Accordingly, it is only desired to arrange optical elements in order to achieve the light path length of the long wavelength component and that of the short wavelength component.

The relationship between the up-chirp phenomenon or the like and the group velocity dispersion value is shown in table 1 as an example. Note that in table 1, the laser light with the up-chirp phenomenon is indicated as “up-chirp laser light,” the laser light with the down-chirp phenomenon is indicated as “down-chirp laser light,” and the laser light with no chirp is indicated as “no-chirp laser light.”

TABLE 1

| | Group velocity | Pulse time width |
|---|---|---|
| Chirp phenomenon | dispersion value | of laser light |
| Up-chirp laser light | Positive | Extended |
| Up-chirp laser light | Negative | Compressed |
| Down-chirp laser light | Positive | Compressed |
| Down-chirp laser light | Negative | Extended |
| No-chirp laser light | Positive | Extended |
| No-chirp laser light | Negative | Extended |

More specifically, in each of the dispersion compensation optical apparatus or the like of the present disclosure (B), the dispersion compensation optical apparatus or the like of the present disclosure (D), the dispersion compensation optical apparatus or the like of the present disclosure (E), and the dispersion compensation optical apparatus according to the second mode of the present disclosure, the group velocity dispersion value is negative. On the other hand, in each of the dispersion compensation optical apparatus or the like of the present disclosure (C) and the dispersion compensation optical apparatus according to the third mode of the present disclosure, the group velocity dispersion value is both positive and negative.

Moreover, in each of the dispersion compensation optical apparatuses according to the first to third modes of the present disclosure including the various desired configurations and forms described above, the semiconductor laser device from which the laser light is emitted may include a mode synchronous semiconductor laser device.

In the semiconductor laser apparatus assembly according to the second mode of the present disclosure, the first dispersion compensation optical apparatus may include any of the dispersion compensation optical apparatuses according to the first to third modes of the present disclosure including the various desired configurations and forms described above. In addition, the second dispersion compensation optical apparatus may include the dispersion compensation optical apparatus according to the first or second mode of the present disclosure, which includes the dispersion compensation optical apparatus or the like of the present disclosure (A), the dispersion compensation optical apparatus or the like of the present disclosure (B), the dispersion compensation optical apparatus or the like of the present disclosure (C), and the dispersion compensation optical apparatus or the like of the present disclosure (D). Moreover, in the semiconductor laser apparatus assembly according to the first or second mode of the present disclosure including the desired configurations and forms described above, the mode synchronous semiconductor laser device desirably has a saturable absorption region. Note that a known light excitation type mode synchronous semiconductor laser device uses the temperature characteristics of a semiconductor saturable absorber (SESAME) to control oscillation characteristics. However, with the saturable absorption region, the oscillation characteristics may be controlled based on reverse bias voltage applied to the saturable absorption region and the group velocity dispersion value (dispersion compensation amount) of a dispersion compensation optical apparatus. Therefore, the control of the oscillation characteristics is facilitated. In this case, the mode synchronous semiconductor laser device may have a lamination structure in which a first compound semiconductor layer made of a GaN-based compound semiconductor and having a first conductive type, a third compound semiconductor layer (active layer) made of the GaN-based compound semiconductor, and a second compound semiconductor layer made of the GaN-based compound semiconductor and having a second conductive type different from the first conductive type are successively laminated one on another. A semiconductor light amplifier is not limited but may have substantially the same configuration and structure as those of the mode synchronous semiconductor laser device.

In each of the dispersion compensation optical apparatuses according to the first to third modes of the present disclosure including the desired forms and configuration described above or in the semiconductor laser apparatus assembly according to the first or second mode of the present disclosure including the desired forms and configurations described above, a wavelength selection unit (wavelength selection apparatus) may be provided to extract the short wavelength component of the laser light finally output to the outside of the system.

Here, the wavelength selection unit may include a band pass filter, a long pass filter, a prism, or an aperture. The aperture may include, e.g., a transmission type liquid crystal display apparatus having a multiplicity of segments. For example, the band pass filter may be obtained in such a manner that a dielectric thin film having a low dielectric constant and a dielectric film having a high dielectric constant are laminated one on the other. In addition, it is also possible to select the wavelength of the laser light emitted from the band pass filter with a change in the incident angle of the pulse-like laser light into the band pass filter.

In the semiconductor laser apparatus assembly according to the first mode of the present disclosure including the dispersion compensation optical apparatus or the like of the present disclosure (A), the dispersion compensation optical apparatus or the like of the present disclosure (B), the dispersion compensation optical apparatus or the like of the present disclosure (C), and the dispersion compensation optical apparatus or the like of the present disclosure (D), or in the semiconductor laser apparatus assembly according to the second mode of the present disclosure in which the first dispersion compensation optical apparatus includes these dispersion compensation optical apparatuses, a partial reflection mirror (also called a partial transmission mirror, a semi-transmission mirror, or a half-mirror) is arranged between the second end face (laser light emitting end face) of the semiconductor laser device and the dispersion compensation optical apparatus or between the second end face of the semiconductor laser device and the first dispersion compensation optical apparatus. Thus, an outside resonator structure includes the first end face (that faces the second end face and serves as a laser light reflection end face) and the partial reflection mirror of the semiconductor laser device. In addition, in the semiconductor laser apparatus assembly according to the first mode of the present disclosure including the dispersion compensation optical apparatus or the like of the present disclosure (E) and the dispersion compensation optical apparatus according to the third mode of the present disclosure, or in the semiconductor laser apparatus assembly according to the second mode of the present disclosure in which the first dispersion compensation optical apparatus includes these dispersion compensation optical apparatuses, the outside resonator structure includes these dispersion compensation optical apparatuses and the first end face.

The length (X′, unit: mm) of the outside resonator is in the range of 0<X′<1500 and desirably in the range of 30≦X′≦500. Here, as described above, the outside resonator includes the first end face of the semiconductor laser device, the reflection mirror or the partial reflection mirror constituting the outside resonator structure, and the dispersion compensation optical apparatus. The length of the outside resonator is a distance between the first end face of the semiconductor laser device, the reflection mirror or the partial reflection mirror constituting the outside resonator structure, and the dispersion compensation optical apparatus.

As a material (diffraction grating member) for constituting the transmission type volume hologram diffraction grating, a photopolymer material may be used. The constituent material and basic structure of the transmission type volume hologram diffraction grating may be the same as those of a known transmission type volume hologram diffraction grating. The transmission type volume hologram diffraction grating indicates a hologram diffraction grating that diffracts and reflects only +first-order diffracted light. The diffraction grating member has interference fringes ranging from the inside to the front face thereof. The interference fringes per se may be formed according to a known forming method. Specifically, for example, object light is applied to the diffraction grating member (e.g., photopolymer material) from a first prescribed direction on one side, while reference light is applied to the diffraction grating member from a second prescribed direction on the other side. Thus, the interference fringes formed by the object light and the reference light are recorded inside the diffraction grating member. By the appropriate selection of the first prescribed direction, the second prescribed direction, and the wavelengths of the object light and reference light, the desired cycle (pitch) and the desired inclination angle (slant angle) of the interference fringes (refractive index modulation degree Δn) of the diffraction grating member may be obtained. The inclination angle of the interference fringes indicates an angle formed by the front face of the transmission type volume hologram diffraction grating and the interference fringes.

In the semiconductor laser apparatus assembly according to the first or second mode of the present disclosure including the desired forms and configurations described above (also collectively and simply called “the semiconductor laser apparatus assembly or the like” of the present disclosure as occasion demands), the mode synchronous semiconductor laser device may include a bi-section type mode synchronous semiconductor laser device in which a light emitting region and a saturable absorption region are arranged side by side in the resonator direction.

In addition, the bi-section type mode synchronous semiconductor laser device may include (a) a lamination structure in which a first compound semiconductor layer having a first conductive type and made of a GaN-based compound semiconductor, a third compound semiconductor layer (active layer) made of the GaN-based compound semiconductor and constituting a light emitting region and a saturable absorption region, and a second compound semiconductor layer having a second conductive type different from the first conductive type and made of the GaN-based compound semiconductor are successively laminated one on another, (b) a band-like second electrode formed on the second compound semiconductor layer, and (c) a first electrode electrically connected to the first compound semiconductor layer.

Moreover, the second electrode may be separated by a separation groove into a first part where direct current is fed to the first electrode via the light emitting region to produce a forward bias state and a second part where an electric field is applied to the saturable absorption region.

Further, the value of the electric resistance between the first and second parts of the second electrode is 1×10 times or more, desirably 1×10² times or more, and more desirably 1×10³ times or more as large as the value of the electric resistance between the first and second electrodes. Note that such a mode synchronous semiconductor laser device is called a “mode synchronous semiconductor laser device having a first configuration” for the sake of convenience. In addition, the value of the electric resistance between the first and second parts of the second electrode is 1×10²Ω or more, desirably 1×10³Ω or more, and more desirably 1×10⁴Ω or more. Note that such a mode synchronous semiconductor laser device is called a “mode synchronous semiconductor laser device having a second configuration” for the sake of convenience.

In the mode synchronous semiconductor laser device having the first or second configuration, direct current is fed from the first part of the second electrode to the first electrode via the light emitting region to produce a forward bias state, and voltage is applied between the first electrode and the second part of the second electrode to add an electric field to the saturable absorption region. Thus, a mode synchronous operation is allowed.

In the mode synchronous semiconductor laser device having the first or second configuration, if the value of the electric resistance between the first and second parts of the second electrode is set to be 10 times or more as large as the value of the electric resistance between the first and second electrodes or set to 1×10²Ω or more, the flow of current leaked from the first part to the second part of the second electrode may be reliably reduced. In other words, since an increase in the reverse bias voltage Vₛₐ applied to the saturable absorption region (carrier non-implantation region) is allowed, a mode synchronous operation having a light pulse whose pulse time width is shorter may be realized. Further, such a high value of the electric resistance between the first and second parts of the second electrode may be achieved in such a manner that the second electrode is separated by the separation groove into the first and second parts.

In addition, the mode synchronous semiconductor laser devices having the first and second configurations are not limited, but the third compound semiconductor layer may have a quantum well structure including a well layer and a barrier layer, the thickness of the well layer may be 1 nm or more and 10 nm or less and desirably 1 nm or more and 8 mm or less, and the concentration of the doped-impurity of the barrier layer may be 2×10¹⁸ cm⁻³ or more and 1×10²⁰ cm⁻³ or less and desirably 1×10¹⁹ cm⁻³ or more and 1×10²⁰ cm⁻³ or less. Note that such a mode synchronous semiconductor laser device is called a “mode synchronous semiconductor laser device having a third configuration” for the sake of convenience. Note that with the employment of the quantum well structure in the active layer, more implantation current amount may be realized compared with the employment of a quantum dot structure, and a high output may be easily obtained.

As described above, if the thickness of the well layer constituting the third compound semiconductor layer is set to 1 nm or more and 10 nm or less and the concentration of the doped-impurity of the barrier layer constituting the third compound semiconductor layer is set to 2×10¹⁸ cm⁻³ or more and 1×10²⁰ cm⁻³ or less, i.e., if the well layer is made thin and the number of the carriers of the third compound semiconductor layer is increased, the influence of piezo polarization may be reduced, and a laser light source having a short pulse time width and capable of generating a single-peak light pulse having a less sub-pulse component may be obtained. In addition, mode synchronous driving is made possible with low reverse bias voltage, and the generation of a light pulse train in synchronization with an outside signal (electric signal and light signal) is made possible. The impurity doped into the barrier layer may include but not limited to silicon (Si), and oxygen (O) may be used.

Here, the mode synchronous semiconductor laser device may be a semiconductor laser device having a ridge stripe type SCH (Separate Confinement Heterostructure). Alternatively, the mode synchronous semiconductor laser device may be a semiconductor laser device having a slant ridge stripe SCH. In other words, the axial line of the mode synchronous semiconductor laser device and that of the ridge stripe structure may cross each other at a prescribed angle. Here, as an example, the prescribed angle θ may be in the range of 0.1°≦0≦10°. The axial line of the ridge stripe structure is a line that connects together bisection points at both ends of the ridge stripe structure in a second end face (laser light emitting end face) and bisection points at both ends of the ridge stripe structure in a first end face (laser light reflection end face) of the lamination structure on the side opposite to the second end face. In addition, the axial line of the mode synchronous semiconductor laser device indicates an axial line orthogonal to the first and second end faces. The plane shape of the ridge stripe structure may be linear or curved.

In addition, if the width of the ridge stripe structure in the second end face is W₂ and that of the ridge stripe structure in the first end face is W₁ in the mode synchronous semiconductor laser device, W₁ may be equal to W₂ or W₂ may be larger than W₁. Note that W₂ may be 5 μm or more, and the upper limit of W₂ may include but not limited to, e.g., 4×10² μm. In addition, W₁ may be in the range of 1.4 μm to 2.0 μm. Each end of the ridge stripe structure may include one line segment or two or more line segments. In the former, for example, the width of the ridge stripe structure may be monotonously moderately expanded in a tapered shape from the first end face to the second end face. In the latter, for example, the width of the ridge stripe structure may be the same at first and then monotonously moderately expanded in a tapered shape from the first end face to the second end face, or may be expanded at first and then narrowed after reaching the maximum width from the first end face to the second end face.

In the mode synchronous semiconductor laser device, the light reflectance of the second end face of the lamination structure to which a laser light beam (laser light pulse) is emitted is desirably 0.5% or less. Specifically, the second end face may have a low reflection coating layer formed thereon. Here, the low reflection coating layer has a lamination structure in which at least two types of layers selected from the group including, e.g., a titanium oxide layer, a tantalum oxide layer, a zirconia oxide layer, a silicon oxide layer, and an aluminum oxide layer are laminated one on the other. Note that the value of the light reflectance is significantly smaller than that of the light reflectance (normally in the range of 5% to 10%) of one end face of a lamination structure to which a laser light beam (laser light pulse) is emitted in a known semiconductor laser device. In addition, the first end face desirably has high light reflectance. For example, it has a light reflectance of 85% or more and desirably a light reflectance of 95% or more.

In the mode synchronous semiconductor laser device, the lamination structure has the ridge stripe structure including at least part of the second compound semiconductor layer in the thickness direction. However, the ridge stripe structure may include only the second compound semiconductor layer, include the second compound semiconductor layer and the third compound semiconductor layer (active layer), or include the second compound semiconductor layer, the third compound semiconductor layer (active layer), and part of the first compound semiconductor layer in the thickness direction.

In the mode synchronous semiconductor laser device having the first or second configuration, although not limited to the following values, the width of the second electrode is 0.5 μm or more and 50 μm or less and desirably 1 μm or more and 5 μm or less, the height of the ridge stripe structure is 0.1 μm or more and 10 μm or less and desirably 0.2 μm or more and 1 μm or less, and the width of the separation groove that separates the second electrode into the first and second parts is 1 μm or more and 50% or less of the length of the resonator of the mode synchronous semiconductor laser device (hereinafter simply called a “resonator length”), and desirably 10 μm or more and 10% or less of the resonator length. The resonator length may include but not limited to 0.6 mm. A distance (D) from the top face of the part of the second compound semiconductor layer positioned outside the both side faces of the ridge stripe structure to the third compound semiconductor layer (active layer) is desirably 1.0×10⁻⁷ m (0.1 μm) or more. If the distance (D) is specified in this manner, the saturable absorption regions may be reliably formed on the sides (Y direction) of the third compound semiconductor layer. The upper limit of the distance (D) may be determined based on an increase in threshold current, temperature characteristics, a reduction in current increase rate at long driving time, or the like. Note that in the following description, the direction of the resonator length will be indicated as an X direction and the direction of the thickness of the lamination structure will be indicated as a Z direction.

Moreover, in the mode synchronous semiconductor laser device having the first or second configuration including the desired forms described above, the second electrode may be made of a palladium (Pd) monolayer, a nickel (Ni) monolayer, a platinum (Pt) monolayer, the lamination structure of a palladium layer and a platinum layer in which the palladium layer is in contact with the second compound semiconductor layer, or the lamination structure of the palladium layer and the nickel layer in which the palladium layer is in contact with the second compound semiconductor layer. Note that if a lower metal layer is made of palladium and an upper metal layer is made of nickel, the thickness of the upper metal layer is desirably 0.1 μm or more and desirably 0.2 μm or more. In addition, the second electrode is desirably made of the palladium (Pd) monolayer. In this case, the thickness of the second electrode is 20 nm or more and desirably 50 nm or more. In addition, the second electrode is desirably made of the palladium (Pd) monolayer, the nickel (Ni) monolayer, the platinum (Pt) monolayer, or the lamination structure of the lower metal layer and the upper metal layer in which the lower metal layer is in contact with the second compound semiconductor layer (however, the lower metal layer is made of one type of metal selected from the group including palladium, nickel, and platinum, and the upper metal layer is made of the metal of which an etching rate for forming the separation groove in the second electrode in the process (D) described later is the same or substantially the same as the etching rate of the lower metal layer or higher than the etching rate of the lower metal layer). In addition, etching liquid for forming the separation groove in the second electrode in the process (D) described later is desirably aqua regia, nitric acid, sulfuric acid, hydrochloric acid, or a mixture of at least two types of these substances (specifically, a mixture of nitric acid and sulfuric acid and a mixture of sulfuric acid and hydrochloric acid).

In the mode synchronous semiconductor laser device having the first or second configuration including the desired configurations and forms described above, the length of the saturable absorption region may be shorter than that of the light emitting region. In addition, the length of the second electrode (the total length of the first and second parts) may be shorter than that of the third compound semiconductor layer (active layer).

Specific examples of the arrangement of the first and second parts of the second electrode may include (1) a state in which the one first part and one second part of the second electrode are provided and the first and second parts of the second electrode are arranged via the separation groove, (2) a state in which the one first part and two second parts of the second electrode are provided, one end of the first part faces one of the two second parts via one separation groove, and the other end of the first part faces the other of the second parts via the other separation groove, and (3) a state in which the two first parts and one second part of the second electrode are provided, one end of the second part faces one of the first parts via one separation groove, and the other end of the second part faces the other of the first parts via the other separation groove (i.e., the second electrode is structured such that the second part is held between the first parts).

In addition, in a broader sense, the specific examples of the arrangement of the first and second parts of the second electrode may include (4) a state in which the N first parts and (N−1) second parts of the second electrode are provided and the first parts of the second electrode are arranged via the second part of the second electrode, and (5) a state in which the N second parts and (N−1) first parts of the second electrode are provided and the second parts of the second electrode are arranged via the first part of the second electrode. Note that the states of (4) and (5) are, respectively, regarded as (4′) a state in which the N light emitting regions (carrier implantation regions and gain regions) and (N−1) saturable absorption regions (carrier non-implantation regions) are provided and the light emitting regions are arranged via the saturable absorption region, and (5′) a state in which the N saturable absorption regions (carrier non-implantation regions) and (N−1) light emitting regions (carrier implantation regions and gain regions) are provided and the saturable absorption regions are arranged via the light emitting region. Note that with the employment of the structures of (3), (5), and (5′), the light emitting end face of the mode synchronous semiconductor laser device is hardly damaged.

The mode synchronous semiconductor laser device may be manufactured according to, e.g., the following method.

That is, the mode synchronous semiconductor laser device may be manufactured according to the method including the following steps (A) to (D).

(A) In step (A), the lamination structure is formed in which the first compound semiconductor layer having the first conductive type and made of the GaN-based compound semiconductor, the third compound semiconductor layer made of the GaN-based compound semiconductor and constituting the light emitting region and the saturable region, and the second compound semiconductor layer having the second conductive type different from the first conductive type and made of the GaN-based compound semiconductor are successively laminated on the substrate one on another.

(B) In step B, the stripe-shaped second electrode is formed on the second compound semiconductor layer.

(C) In step C, at least part of the second compound semiconductor layer is etched using the second electrode as an etching mask to form the ridge stripe structure.

(D) In step D, a resist layer for forming the separation groove in the second electrode is formed, and the separation groove is formed according to a wet etching method using the resist layer as a wet etching mask. Thus, the second electrode is separated by the separation groove into the first and second parts.

As described above, the ridge stripe structure is formed according to such a manufacturing method, i.e., the method in which at least part of the second compound semiconductor layer is etched using the stripe-shaped second electrode as the etching mask. In other words, the ridge stripe structure is formed according to a self alignment method using the patterned second electrode as the etching mask. Therefore, no positional deviation occurs between the second electrode and the ridge stripe structure. In addition, the separation groove is formed in the second electrode according to the wet etching method. Thus, with the employment of the wet etching method rather than a dry etching method, the degradation of optical and electrical characteristics in the second compound semiconductor layer may be reduced. Therefore, it is possible to reliably prevent the degradation of light emitting characteristics.

Note that in step (C), the second compound semiconductor layer may be partially etched in the thickness direction or may be entirely etched in the thickness direction. Further, the second and third compound semiconductor layers may be etched in the thickness direction. Furthermore, the first, second, and third compound semiconductor layers may be partially etched in the thickness direction.

Moreover, assuming that the etching rate of the second electrode is ER₀ and that of the lamination structure is ER₁ in forming the separation groove in the second electrode in step (D), it is desirable to satisfy the relational expression ER₀/ER₁≧1×10 and desirably the relational expression ER₀/ER₁≧1×10². If ER₀/ER₁ satisfies such a relational expression, the second electrode may be reliably etched without etching the lamination structure (or the lamination structure is slightly etched).

In the mode synchronous semiconductor laser device, the lamination structure may be specifically made of an AlGaInN-based compound semiconductor. Here, more specific examples of the AlGaInN-based compound semiconductor may include GaN, AlGaN, GaInN, and AlGaInN. Such compound semiconductors may contain a boron (B) atom, a thallium (Tl) atom, an arsenic (As) atom, a phosphorus (P) atom, and a stibium (Sb) atom as occasion demands. In addition, the third compound semiconductor layer (active layer) constituting the light emitting region (gain region) and the saturable absorption region desirably has a quantum well structure. Specifically, the third compound semiconductor layer may have a single quantum well structure (QW structure) or a multi-quantum well structure (MQW structure). The third compound semiconductor layer (active layer) having the quantum well structure has a structure in which at least one of the well layer and the barrier layer is laminated. However, as the combinations of (the compound semiconductor constituting the well layer and the compound semiconductor constituting the barrier layer), (In_{y}Ga_{(1-y)}N, GaN), (In_{y}Ga_{(1-y)}N, In_{z}Ga_{(1-Z)}N) (where y>Z), and (In_{y}Ga_{(1-y)}N, AlGaN) may be exemplified.

Moreover, in the mode synchronous semiconductor laser device, the second compound semiconductor layer may have a superlattice structure in which p type GaN layers and p type AlGaN layers are alternately laminated one on another, and the thickness of the superlattice structure may be 0.7 μm or less. With the employment of such a superlattice structure, the series resistance component of the mode synchronous semiconductor laser device may be reduced while maintaining a refractive index necessary as a cladding layer, which results in a reduction in the operation voltage of the mode synchronous semiconductor laser device. Note that although not limited to the following values, the lower limit of the thickness of the superlattice structure may be, e.g., 0.3 μm, the thickness of the p type GaN layers constituting the superlattice structure may be in the range of 1 nm to 5 nm, the thickness of the p type AlGaN layers constituting the superlattice structure may be in the range of 1 nm to 5 nm, and the total number of the p type GaN layers and the p type AlGaN layers may be in the range of 60 to 300. In addition, a distance from the third compound semiconductor layer to the second electrode may be 1 μm or less and desirably 0.6 μm or less. With the specification of the distance from the third compound semiconductor layer to the second electrode as described above, it is possible to reduce the thickness of the p type second compound semiconductor layer having high resistance and attain the reduction of the operation voltage of the mode synchronous semiconductor laser device. Note that the lower limit of the distance from the third compound semiconductor layer to the second electrode may be, although not limited to, e.g., 0.3 μm. In addition, Mg is doped into the second compound semiconductor layer by 1×10¹⁹ cm⁻³ or more, and the absorption coefficient of the second compound semiconductor layer with respect to the light having a wavelength of 405 nm emitted from the third compound semiconductor layer may be at least 50 cm⁻¹. The atomic concentration of Mg is derived from the material properties in which the maximum hole concentration is shown at a value of 2×10¹⁹ cm⁻³, and is set so as to have the maximum hole concentration, i.e., the minimum specific resistance of the second compound semiconductor layer. The absorption coefficient of the second compound semiconductor layer is specified from the viewpoint of reducing the resistance of the mode synchronous semiconductor laser device to a greater extent. As a result, the absorption coefficient of the light of the third compound semiconductor layer is generally set to 50 cm⁻¹. However, in order to increase the absorption coefficient, it is also possible to intentionally set the doped amount of Mg to a concentration of 2×10¹⁹ cm⁻³ or more. In this case, the upper limit of the doped amount of Mg is set to, e.g., 8×10¹⁹ cm⁻³ to obtain practical hole concentration. In addition, the second compound semiconductor layer may have a non-doped compound semiconductor layer and a p type compound semiconductor layer from the side of the third compound semiconductor layer, and a distance from the third compound semiconductor layer to the p type compound semiconductor layer may be 1.2×10⁻⁷ m or less. With the specification of the distance from the third compound semiconductor layer to the p type compound semiconductor layer as described above, internal loss may be prevented unless internal quantum efficiency is reduced. Thus, a threshold current density at which laser oscillation is started may be reduced. Note that the lower limit of the distance from the third compound semiconductor layer to the p type compound semiconductor layer may be, although not limited to, e.g., 5×10⁻⁸ m. In addition, lamination insulation films having an SiO₂/Si lamination structure may be formed on both sides faces of the ridge stripe structure, and the difference between the effective refractive index of the ridge stripe structure and that of the lamination insulation films may be in the range of 5×10⁻³ to 1×10⁻². With the use of such lamination insulation films, a single fundamental lateral mode may be maintained even at a high output operation exceeding 100 mw. In addition, the second compound semiconductor layer may have a structure in which a non-doped GaInN layer (p side light guide layer), an Mg-doped AlGaN layer (electron barrier layer), the superlattice structure (superlattice cladding layer) of a GaN layer (Mg-doped)/AlGaN layer, and an Mg-doped GaN layer (p side contact layer) are laminated from the side of the third compound semiconductor layer one on another. The band gap of a compound semiconductor constituting a well layer in the third compound semiconductor layer is desirably 2.4 eV or more. In addition, the wavelength of the laser light emitted from the third compound semiconductor layer (active layer) is in the range of 360 nm to 500 nm and desirably in the range of 400 nm to 410 nm. Here, it is needless to say that the above various configurations may be appropriately combined together.

In the mode synchronous semiconductor laser device, various GaN-based compound semiconductor layers constituting the mode synchronous semiconductor laser device are successively formed on a substrate. Here, examples of the substrate may include, besides a sapphire substrate, a GaAs substrate, GaN substrate, SiC substrate, alumina substrate, ZnS substrate, ZnO substrate, AlN substrate, LiMgO substrate, LiGaO₂ substrate, MgAl₂O₄ substrate, InP substrate, Si substrate, and these substrates having a grounding layer and a buffer layer formed on the front face (principal face) thereof. If the GaN-based compound semiconductor layer is mainly formed on the substrate, it is desirable to use the GaN substrate for its low defect density. However, it has been known that the GaN substrate changes its characteristics between polarity, non-polarity, and semi-polarity depending on its growth face. In addition, examples of a method for forming the various compound semiconductor layers (e.g., the GaN-based compound semiconductor layer) constituting the mode synchronous semiconductor laser device may include a metal organic chemical vapor deposition method (MOCVD method, i.e., MOVPE method), a molecular beam epitaxy method (MBE method), and a hydride vapor growth method in which a halogen contributes to transportation or reaction.

Here, examples of an organic gallium source gas in the MOCVD method may include a trimethyl gallium (TMG) gas and a triethyl gallium (TEG) gas, and examples of a nitrogen source gas may include an ammonium gas and a hydrazine gas. In addition, in forming the GaN-based compound semiconductor layer having n type conductive type, silicon (Si) may be, e.g., added as an n type impurity (n type dopant). In forming the GaN-based compound semiconductor layer having p type conductive type, magnesium (Mg) may be, e.g., added as a p type impurity (p type dopant). In addition, if aluminum (Al) or indium (In) is contained as the constituent atom of the GaN-based compound semiconductor layer, a trimethyl aluminum (TMA) gas may be used as an Al source or a trimethyl indium (TMI) gas may be used as an In source. Moreover, a monosilane gas (SiH₄ gas) may be used as an Si source, and a cyclopentadienyl magnesium gas, methylcyclopentadienyl magnesium, biscyclopentadienyl magnesium (Cp₂Mg) may be used as Mg sources. Note that examples of the n type impurity (n type dopant) may include, besides Si, Ge, Se, Sn, C, Te, S, O, Pd, and Po, and examples of the p type impurity (p type dopant) may include, besides Mg, Zn, Cd, Be, Ca, Ba, C, Hg, and Sr.

If the first conductive type is an n type, the first electrode electrically connected to the first compound semiconductor layer having the n type conductive type desirably has a monolayer configuration or a multi-layer configuration containing at least one type of metal selected from the group including gold (Au), silver (Ag), palladium (Pd), aluminum (Al), titanium (Ti), tungsten (W), copper (Cu), zinc (Zn), tin (Sn), and indium (In). Among the substances, the configuration may include, e.g., Ti and Au, Ti and Al, Ti, Pt, and Au. The first electrode is electrically connected to the first compound semiconductor layer. In this case, the first electrode is formed on the first compound semiconductor layer or connected to the first compound semiconductor layer via a conductive material layer or a conductive substrate. The first and second electrodes may be deposited according to, e.g., a PVD method such as a vacuum deposition method and a sputtering method.

On the first and second electrodes, a pad electrode may be provided so as to be electrically connected to an outside electrode or circuit. The pad electrode desirably has a monolayer configuration or multi-layer configuration containing at least one type of metal selected from the group including titanium (Ti), aluminum (Al), platinum (Pt), gold (Au), and nickel (Ni). Alternatively, the pad electrode may have the multi-layer configuration including Ti, Pt, and Au or Ti and Au.

In the mode synchronous semiconductor laser device having the first or second configuration, reverse bias voltage is desirably applied between the first electrode and the second part (i.e., the first electrode is set to have positive polarity and the second part is set to have negative polarity) as described above. Note that pulse current or pulse voltage in synchronization with the pulse current or pulse voltage applied to the first part of the second electrode may be applied to the second part of the second electrode, or a direct current bias may be applied thereto. In addition, current may be fed from the second electrode to the first electrode via the light emitting region, and an outside electric signal may be superimposed on the first electrode from the second electrode via the light emitting region. Thus, it is possible to synchronize a laser light pulse and the outside electric signal with each other. In addition, it is possible to cause a light signal to be incident on one end face of the lamination structure. Also in this case, it is possible to synchronize the laser light pulse and the light signal with each other. In addition, in the second compound semiconductor layer, the non-doped compound semiconductor layer (e.g., non-doped GaInN layer or non-doped AlGaN layer) may be formed between the third compound semiconductor layer and the electron barrier layer. Moreover, the non-doped GaInN layer may be formed as a light guide layer between the third compound semiconductor layer and the non-doped compound semiconductor layer. The top of the second compound semiconductor layer may be occupied with the Mg-doped GaN layer (p side contact layer).

The mode synchronous semiconductor laser device is not limited to a bi-section type (two-electrode type) semiconductor laser device, but may include a multi-section type (multi-electrode type) semiconductor laser device, a SAL (Saturable Absorber Layer) type in which a light emitting region and a saturable absorption region are arranged in the vertical direction, and a WI (Weakly Index guide) type semiconductor laser device in which a saturable absorption region is provided along a ridge stripe structure.

The semiconductor laser apparatus assembly of the present disclosure is applicable to, e.g., optical disk systems, communication fields, optical information fields, opto-electronic integrated circuits, fields to which a non-linear optical phenomenon is applied, optical switches, laser measurement fields, various analysis fields, super high-speed spectral analysis fields, multi-photon excitation spectral analysis fields, mass analysis fields, microspectrophotometry fields using multi-photon absorption, quantum control of chemical reaction, three-dimensional nano-processing fields, various processing fields to which multi-photon absorption is applied, medical fields, and bio imaging fields.

Hereinafter, prior to the description of the dispersion compensation optical apparatuses and the semiconductor laser apparatus assemblies of the present disclosure based on the embodiments, a description will be given of the principle or the like of the dispersion compensation optical apparatuses of the present disclosure.

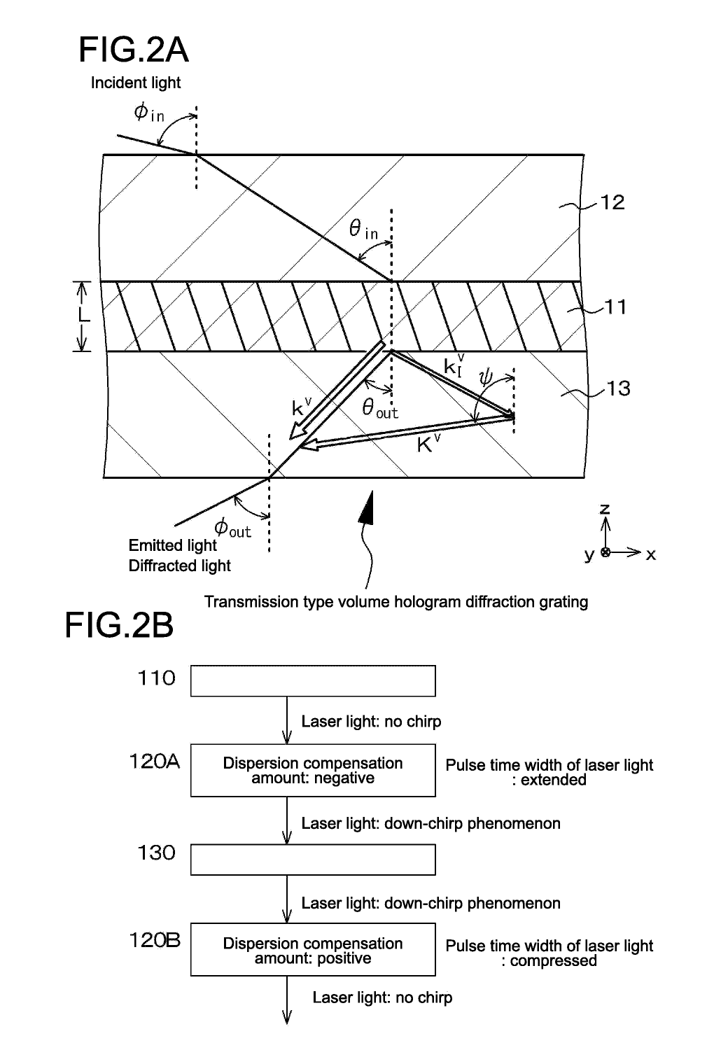

FIG. 2A shows the schematic partial cross-sectional diagram of the transmission type volume hologram diffraction grating. In the transmission type volume hologram diffraction grating, a diffraction grating member (photopolymer material) 11 having a thickness L is held between two glass substrates 12 and 13 (refractive index: N). The diffraction grating member 11 has a periodical parallel refractive index modulation degree Δn (indicated by a thick oblique line in FIG. 2A) formed therein using two-light flux interference. Assuming that the wave number vector of incident light is k_{I}^{V}, the wave number vector of diffracted light is k^{v}, and the reciprocal lattice vector of the periodic modulation of a refractive index (hereinafter called “diffraction grating vector”) is K^{V}, conditions on which the incident light is diffracted are given by the following formula (1). Here, m indicates an integer. Note that in order to indicate the vectors, superscripts “v” are given for the sake of convenience.

k_{I}^{v}+m·K^{v}=k^{v} (1)

Here, the wave number vectors k_{I}^{v} and k^{v} of the incident light and the diffracted light are wave number vectors inside the glass substrates 12 and 13, and the angle of laser light incident on the dispersion compensation optical apparatus (more specifically, the glass substrate 12) and the angle of the laser light emitted from the dispersion compensation optical apparatus (more specifically, the glass substrate 13) are indicated as φᵢₙ and φₒᵤₜ, respectively. Note that, as described above, the incident angle φᵢₙ and the emitting angle φₒᵤₜ are angles formed with respect to the normal line of the incident face of the laser light of the transmission type volume hologram diffraction grating. Here, the diffraction grating vector K^{v} is given by the following formula (2) using the period P of the refractive index modulation degree Δn. In addition, the size of the diffraction grating vector K^{v} is given by the following formula (3) based on the angle θᵢₙ of the laser light incident on the diffraction grating member 11, the angle θₒᵤₜ (diffraction angle) of the laser light emitted from the diffraction grating member 11, and the wavelength λ of the incident light. Accordingly, the period P of the refractive index modulation degree Δn is given by the following formula (4).

|K^{V}|=2π/P (2)

K=k[{sin(θᵢₙ)+sin(θₒᵤₜ)}²+{cos(θᵢₙ)−cos(θₒᵤₜ)}²]^{1/2}=k[2{1−cos(θᵢₙ+θₒᵤₜ)}]^{1/2} (3)

P=λ/[2{1−cos(θᵢₙ+θₒᵤₜ)}]^{1/2} (4)

Meanwhile, because the diffraction conditions of formula (1) do not lose generality in consideration of only a component (x component in FIG. 2A) inside the diffraction grating face of each vector, formula (1) may be rewritten as the following formula (5).

k_{I,x}^{v}+m·Kₓ^{v}=kₓ^{v} (5)

If the relationship between the incident angle φᵢₙ and the emitting angle (diffraction angle) φₒᵤₜ of the laser light with respect to the transmission type volume hologram diffraction grating is calculated from formula (5), the following formula (6) is obtained.

sin(θᵢₙ)+m·(λ/P)·sin(φ)=sin(φₒᵤₜ) (6)

Here, φ indicates an angle formed by the normal line of the transmission type volume hologram diffraction grating and the diffraction grating vector K^{v}, and the relationship between the incident angle θᵢₙ and the diffraction angle θₒᵤₜ of the light with respect to the diffraction grating member 11 is indicated by the following formula (7).

sin(φ)={sin(θᵢₙ)+sin(θₒᵤₜ)}/[2{1−cos(θᵢₙ+θₒᵤₜ)}]^{1/2} (7)

The dependence of the angular dispersion of the diffracted light with respect to a wavelength may be calculated from formula (6), which is indicated by the following formula (8).

dφₒᵤₜ/dλ={sin(θᵢₙ)+sin(θₒᵤₜ)}/{N·λ·cos(θₒᵤₜ)} (8)

In the dispersion compensation optical apparatuses of the present disclosure, the wavelength dependence of the spatial dispersion indicated by formula (8) is used for the compression and expansion of an ultra short pulse. In addition, a high throughput as a target of the present disclosure is determined by the diffraction efficiency of the transmission type volume hologram diffraction grating. Further, the diffraction efficiency may be approximated by the following formula (9).

η=sin²[(π·Δn·L)/2λ{cos(θᵢₙ)·cos(θₒᵤₜ)}^{1/2}]·Sinc²[Δk_{z}·(L/2)] (9)

Here, the term of sin² is the coupling constant of the incident light and the diffracted light determined by the refractive index modulation degree Δn and the thickness L of the diffraction grating member constituting the transmission type volume hologram diffraction grating, and the term of Sinc² corresponds to a change in diffraction efficiency in a case in which a wavelength is deviated from the Bragg's diffraction conditions (see Non-Patent Literature “Femtosecond laser pulse compression using volume phase transmission holograms” by Tsung-Yuan Yang, et al., Applied Optics, 1 Jul. 1985, Vol. 24, No. 13). The band of the diffraction wavelength is determined by the spread of the reciprocal lattice vector permitted inside the transmission type volume hologram diffraction grating. The difference Δk of the wave number vector with a change in incident wavelength is given by the following formula (10).

Δk=2π·N{1/(λ+Δλ)−1/λ}≈−(2π·N)(Δλ/λ²) (10)

On this occasion, the wave number vector component Δkz inside the diffraction grating face is given by the following formula (11).

Δk_{z}=Δk{1−cos(θᵢₙ+θₒᵤₜ)}/cos(θₒᵤₜ) (11)

By formula (11), the diffraction efficiency with respect to the wavelength band necessary for pulse compression may be approximated as in the following formula (12).

η=sin² [(π·Δ·L)/2π{cos(θᵢₙ)−cos(θₒᵤₜ)}^{1/2}]·Sinc²[π·N·L·(Δλ/λ²){1−cos(θᵢₙ+θₒᵤₜ)}/cos(θₒᵤₜ)] (12)

Next, the conditions of the transmission type volume hologram diffraction grating satisfying desired requirements are calculated from formula (12). Here, formula (12) is described as the product of the two functions and includes the term proportional to sin² indicating the diffraction efficiency with the refractive index modulation degree Δn and the term proportional to Sinc² depending on a difference in the wave number vector between the incident light and the diffracted light.

The dispersion compensation optical apparatus of the present disclosure satisfies the requirements of (A) a high throughput of 90% or more and (B) large spatial dispersion. In addition, in the dispersion compensation optical apparatus according to the first mode of the present disclosure, (C) the sum of the incident angle φᵢₙ of the laser light and the emitting angle φₒᵤₜ of the first-order diffracted light is 90°.

(A) Realization of High Throughput

In realizing a high throughput, it is desired to realize the highest possible diffraction efficiency in a desired wavelength band. In formula (12), only the term of Sinc² depends on the wavelength band. Therefore, assuming that the term of sin² is “1” under appropriate conditions, the following formula (13) is obtained.

η≈Sinc²[π·N·L·(Δλ/λ²){1−cos(θᵢₙ+θₒᵤₜ)}/cos(θₒᵤₜ)] (13)

In order to obtain the relational expression 90% in formula (13), it is desired to satisfy the following formula (14).

|π·N·L·(Δλ/λ²){1−cos(θᵢₙ+θₒᵤₜ}/cos(θₒᵤₜ)|≦0.553 (14)

Here, “0.553” is a value such that the term of Sinc² described above becomes 0.9 or more. Thus, the conditions of the thickness L of the diffraction grating member constituting the transmission type volume hologram diffraction grating and the refractive index N for satisfying the band (laser light spectrum width as a target for pulse compression/extension) Δλ in the desired wavelength λ are derived as in the following formula (15) or formula (A).

|{1−cos(θᵢₙ+θₒᵤₜ)}/cos(θₒᵤₜ)|≦{0.553/(π·N·L)}(λ²/Δλ) (15)/(A)

Formula (15) may be described by the pulse width Δτ of the laser light pulse as a target for compression and extension. The time width Δτ and the frequency width Δν of the light pulse, which may be compressed by the dispersion compensation optical apparatus, are indicated by the following relational expression if a light pulse waveform is a Gaussian function. However, the relational expression is changed into an equation if the pulse is at the Fourier limit.

Δτ·Δν≦0.441 (16)

In addition, using the wavelength λ, wavelength width Δλ, and light speed C₀ (2.99792458×10⁸ m/sec), the frequency width Δν may be approximated as in the following formula (17) if the relational expression X>>Δλ is established.

Δν=C₀{1/λ−1/(λ+Δλ)}≈C₀(Δλ/λ²) (17)

Using formula (17), the inequality of the product of time band widths may be rewritten by the light speed and wavelength band as in the following formula (18).

Δτ≦(0.441/Δν)≈0.441{λ²/(C₀·Δλ)} (18)

Based on formula (18), the conditions on the thickness L of the diffraction grating member may be rewritten as in the following formula (19) using the width Δτ of the shortest pulse capable of being compressed.

|{1−cos(θᵢₙ+θₒᵤₜ)}/cos(θₒᵤₜ)|≦(0.553·Δτ·C₀)/(0.441π·N·L) (19)

Note that since the Gaussian type function is assumed as a pulse waveform, the minimum value of the product of time width bands is set to “0.441.” However, it is also possible to assume other pulse waveforms. For example, in the case of a Sech² type function, the minimum value of the product of time band widths may be set to “0.315.”

(B) Large Spatial Dispersion

In order to constitute a small dispersion compensation optical apparatus, it is desired to increase the angular dispersion of the transmission type volume hologram diffraction grating. To this end, it is desired to increase angular dispersion dependence with respect to the wavelength given by formula (8). The angular dispersion of an engraved diffraction grating having the same engraved line as that of the period P of the refractive index modulation degree Δn is given by the following formula (20).

dφₒᵤₜ/dλ=1/{P cos(θₒᵤₜ)}≦2/{λ cos(θₒᵤₜ)} (20)

From the comparison between formulae (20) and (8), it appears that the angular dispersion is reduced by about 1/(2N) in the transmission type volume hologram diffraction grating. In view of this, consideration is given to the relational expression sin(θᵢₙ)+sin(θₒᵤₜ)≧1 as conditions for obtaining the spatial dispersion about one-third of that of the engraved diffraction grating. If the angle conditions are converted into the conditions of {1−cos(θᵢₙ+θₒᵤₜ)}/cos(θₒᵤₜ), they may be approximated as in the following formula (21).

{1−cos(θᵢₙ+θₒᵤₜ)}/cos(θₒᵤₜ)>0.3 (21)

When the conditions are made correspond to formula (15) or formula (19) described above, the following formula (22) is obtained based on the description of the wavelength band and the following formula (23) is obtained based on the description of the pulse width as the conditions of the thickness L of the diffraction grating member constituting the transmission type volume hologram diffraction grating. Note that the conditions are the conditions of the pulse width and the thickness L of the term of Sinc².

L≦{0.553/(0.3·π·N)}(λ²/Δλ) (22)

L≦(0.553·Δτ·C₀)/(0.3×0.441·π·N) (23)

Moreover, conditions for maximizing the term of sin² are given by the following formula (24).

L={(1+2m)·λ/Δn}·{cos(θᵢₙ)·cos(θₒᵤₜ)}^{1/2} (24)

Further, conditions for setting the diffraction efficiency to 90% or more using formula (24) are based on the following formula (25) or formula (B).

{(0.8+2m)·λ/Δn}·{cos(θᵢₙ)·cos(θₒᵤₜ)}^{1/2}≦L≦{(1.2+2m)·λ/Δn}·{cos(θᵢₙ)·cos(θₒᵤₜ)}^{1/2} (25)/(B)

If the refractive index modulation degree Δn of the diffraction grating member 11 is a given one, the thickness L of the diffraction grating member 11 desirably satisfies the above conditions. Because the refractive index modulation degree Δn also depends on the exposure time of the two-light-flux interference, it is not easy to uniquely determine the refractive index modulation degree Δn. However, the upper limit is determined by the properties of the diffraction grating member 11. For this reason, the conditions for specifying the thickness L of the diffraction grating member 11 based on the refractive index modulation degree Δn are described.

(C) Discussion of a Case in which the Sum of the Incident Angle φᵢₙ of Laser Light and the Emitting Angle φ_{Out} of First-Order Diffracted Light is 90°

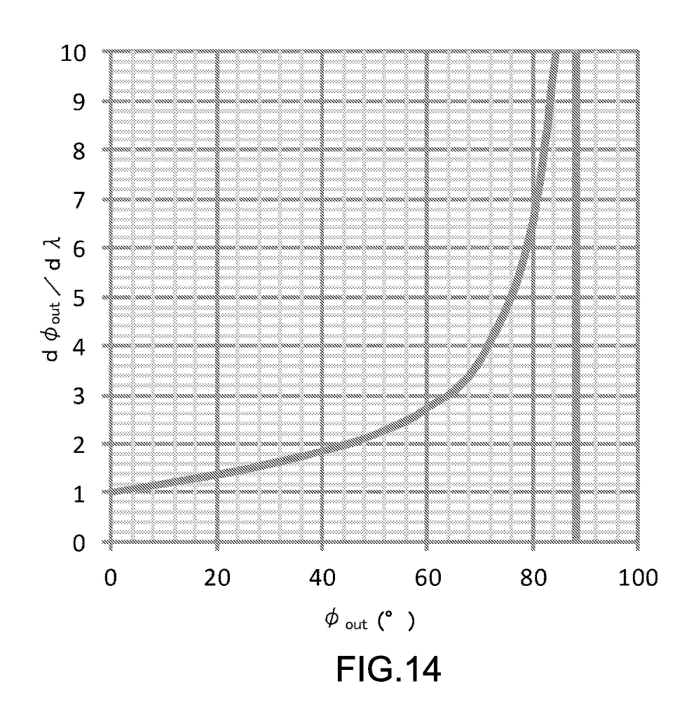

In order to constitute the dispersion compensation optical apparatus whose light axis is easily adjusted, it is desired to satisfy the relational expression φᵢₙ+φₒᵤₜ=90°. In particular, if the relational expression φₒᵤₜ>φᵢₙ is established, the angular dispersion in formula (8) may be made large. FIG. 14 shows the dependence dφₒᵤₜ/dλ of the spatial dispersion with respect to φₒᵤₜ.

Hereinafter, a description will be given of an example of calculating the diffraction efficiency of the transmission type volume hologram diffraction grating in cases in which the relational expressions φᵢₙ≈φₒᵤₜ and θᵢₙ≈φₒᵤₜ are established.

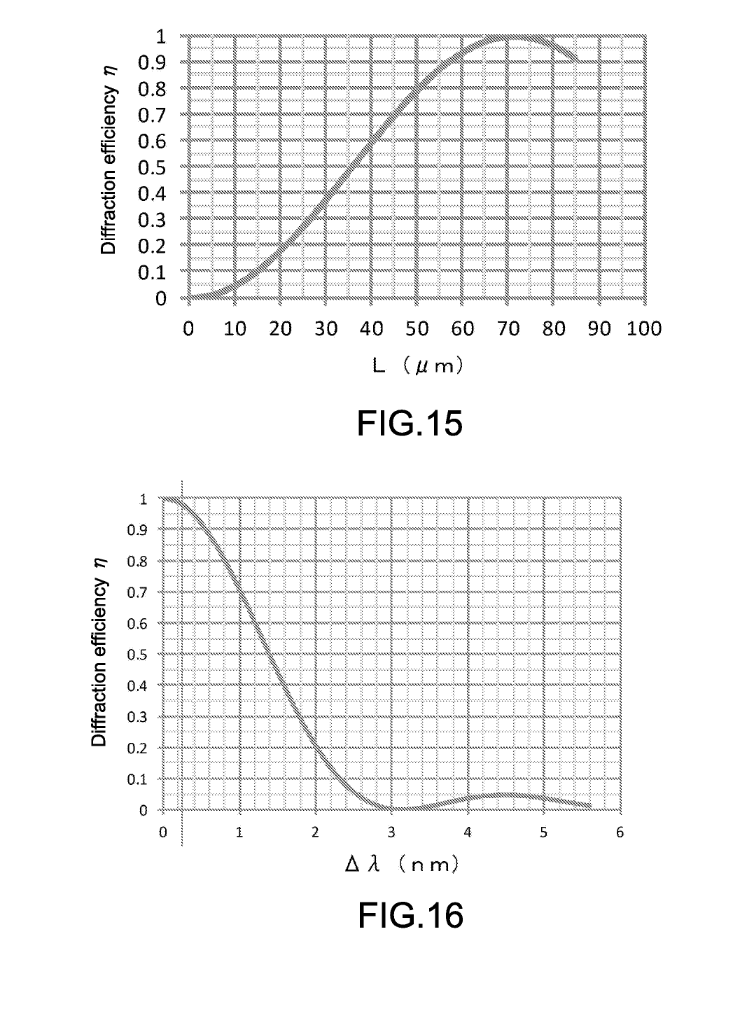

FIG. 15 shows the result of calculating the term of sin² depending on the refractive index modulation degree Δn. In this calculation, the wavelength is fixed in formula (12) to extract a term proportional to the term of sin². In addition, the following values are used. If the relational expression L=70 μm is established, the term proportional to the term of sin² becomes the maximum.

Refractive index modulation degree Δn=0.005

Wavelength λ=405 nm

Incident angle θᵢₙ with respect to the diffraction grating member=28°

Next, FIG. 16 shows a change in the diffraction efficiency when the spectrum width of the incident light is changed under the conditions of L=70 μm, the refractive index modulation degree Δn=0.005, and the wavelength λ=405 nm. Although the remarkable wavelength dependence is confirmed, the spread of a wavelength indicating a diffraction efficiency of 95% or more is about ±0.2 nm with respect to the light having a wavelength of 405 μm. The spread of the wavelength corresponds to the pulse time width of about 0.6 picosecond in an ultra short pulse at the Fourier transform limit, and refers to a wavelength band applicable to an ultra short pulse having a time width broader than the pulse width. Accordingly, it is possible to apply the spread of the wavelength to a laser light pulse generated by the mode synchronous semiconductor laser device made of the InGaN compound semiconductor.

With the appropriate selection of the conditions of the refractive index modulation degree Δn as described above, the transmission type volume hologram diffraction grating having a diffraction efficiency of 90% or more may be realized at a desired wavelength and a desired diffraction angle. Further, with the use of the transmission type volume hologram diffraction grating, it is possible to achieve a throughput of 80% or more in the entire dispersion compensation optical apparatus to be described in the following embodiments.

### First Embodiment

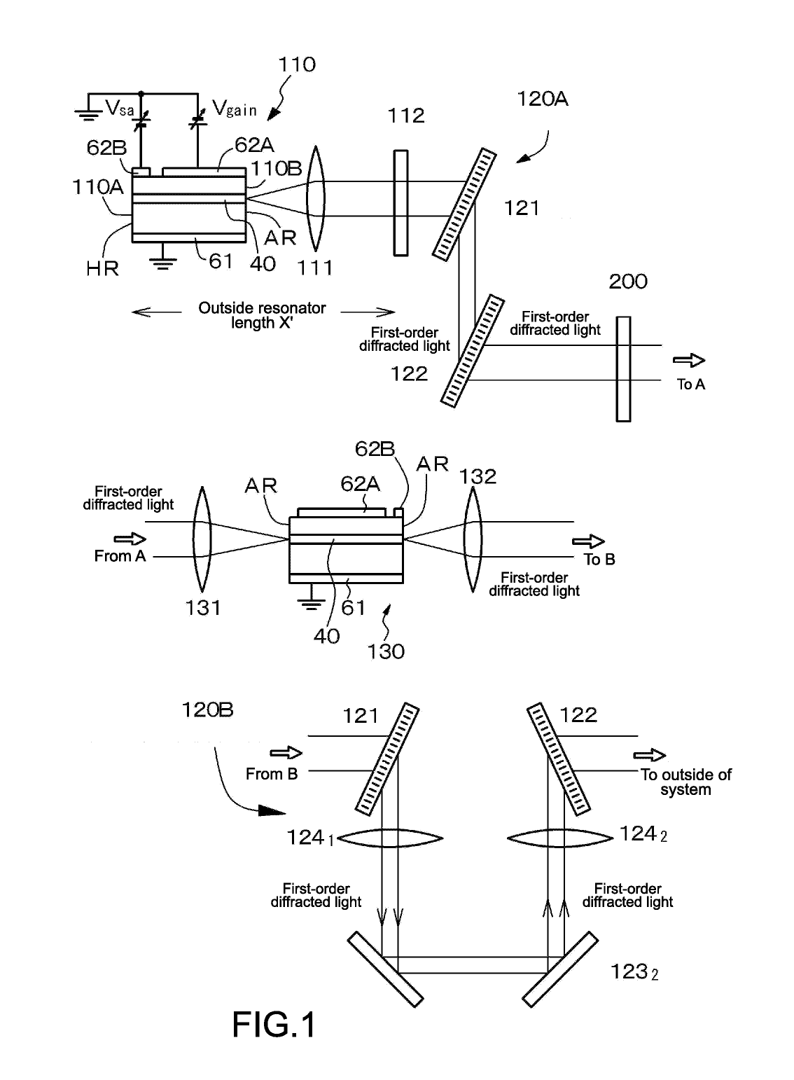

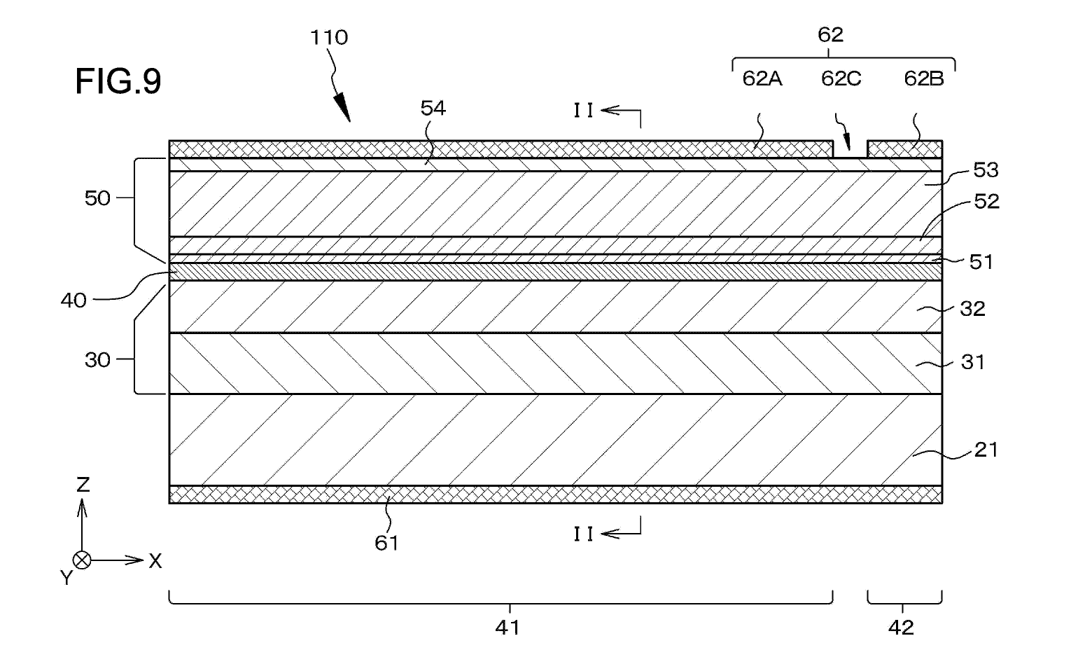

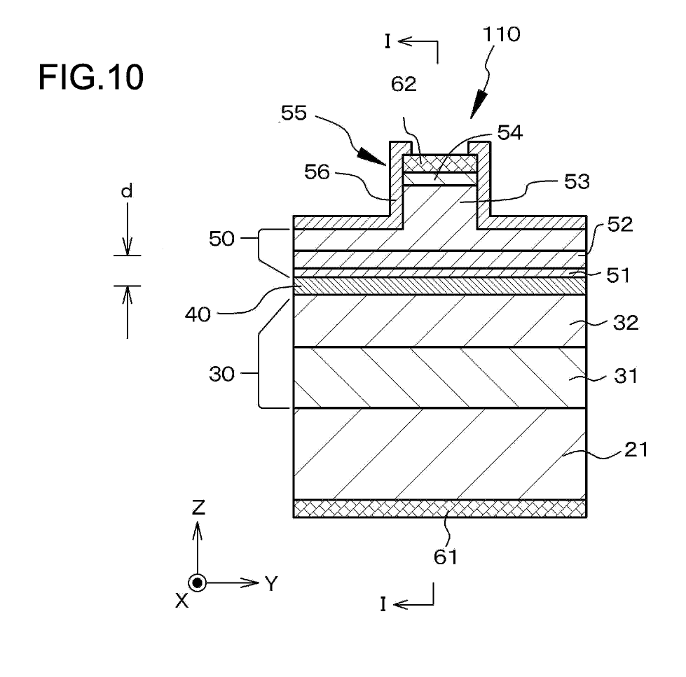

The first embodiment relates to the dispersion compensation optical apparatuses according to the first mode of the present disclosure and more specifically to the dispersion compensation optical apparatus or the like of the present disclosure (A) and the dispersion compensation optical apparatus or the like of the present disclosure (C). Moreover, the first embodiment relates to the semiconductor laser apparatus assembly according to the first mode of the present disclosure and the semiconductor laser apparatus assembly according to the second mode of the present disclosure. FIG. 1 shows the conceptual diagram of the semiconductor laser apparatus assembly of the first embodiment, and FIG. 2B shows the outline of the chirp phenomenon in the semiconductor laser apparatus assembly of the first embodiment. Note that as described above, FIG. 2A shows the schematic partial cross-sectional diagram of the transmission type volume hologram diffraction grating. In addition, FIG. 9 shows the schematic diagram of an end face along a direction in which the resonator of a mode synchronous semiconductor laser device 110 extends, and FIG. 10 shows a schematic cross-sectional diagram along a direction perpendicular to the direction in which the resonator of the mode synchronous semiconductor laser device extends.

The dispersion compensation optical apparatuses 120A and 120B of the first embodiment include two transmission type volume hologram diffraction gratings (first and second transmission type volume hologram diffraction grating 121 and 122) arranged facing each other. In each of the transmission type volume hologram diffraction gratings 121 and 122, the sum of the incident angle φᵢₙ of the laser light and the emitting angle φₒᵤₜ of the first-order diffracted light is 90°. In other words, the relational expression (φᵢₙ+φₒᵤₜ=90° is established. Note that in each of the dispersion compensation optical apparatuses, the semiconductor laser device that emits the laser light includes a mode synchronous semiconductor laser device.

With the adjustment of the distance between the first and second transmission type volume hologram diffraction gratings 121 and 122, the group velocity dispersion value (dispersion compensation amount) of the dispersion compensation optical apparatuses may be controlled. Meanwhile, if the value of (φᵢₙ+φₒᵤₜ) is not 90°, an increase in the distance between the first and second transmission type volume hologram diffraction gratings 121 and 122 results in a change in the position of the first-order diffracted light emitted from the dispersion compensation optical apparatuses. Therefore, with the change in the group velocity dispersion value (dispersion compensation amount), it is desired to adjust an optical system correspondingly. However, if the value of (φᵢₙ+φₒᵤₜ) is set to 90°, no change occurs in the position of the first-order diffracted light emitted from the dispersion compensation optical apparatuses, which facilitates the adjustment of the group velocity dispersion value (dispersion compensation amount).

In addition, the semiconductor laser apparatus assemblies of the first embodiment include the mode synchronous semiconductor laser device 110 and the dispersion compensation optical apparatus 120A of the first embodiment on which the laser light emitted from the mode synchronous semiconductor laser device 110 is incident. In addition, the semiconductor laser apparatus assemblies of the first embodiment include the mode synchronous semiconductor laser device 110, the first dispersion compensation optical apparatus 120A on which the laser light emitted from the mode synchronous semiconductor laser device 110 is incident, a semiconductor light amplifier 130 on which the laser light emitted from the first dispersion compensation optical apparatus 120A is incident, and the second dispersion compensation optical apparatus 120B on which the laser light emitted from the semiconductor light amplifier 130 is incident. Note that the first dispersion compensation optical apparatus 120A includes the dispersion compensation optical apparatus or the like of the present disclosure (A), and the second dispersion compensation optical apparatus 120B includes the dispersion compensation optical apparatus or the like of the present disclosure (C).

The first and second transmission type volume hologram diffraction gratings 121 and 122 are arranged parallel to each other. Further, in the dispersion compensation optical apparatuses 120A and 120B of the first embodiment, the emitting angle φₒᵤₜ of the first-order diffracted light is larger than the incident angle φᵢₙ of the laser light in the first transmission type volume hologram diffraction grating 121 on which the laser light emitted from the mode synchronous semiconductor laser device 110 is incident. In other words, the relational expression φₒᵤₜ>φᵢₙ is established. On the other hand, the emitting angle φₒᵤₜ of the first-order diffracted light is smaller than the incident angle φᵢₙ of the laser light in the second transmission type volume hologram diffraction grating 122 on which the first-order diffracted light emitted from the first transmission type volume hologram diffraction grating 121 is incident (i.e., φₒᵤₜ<φᵢₙ). Moreover, the incident angle φᵢₙ of the laser light in the first transmission type volume hologram diffraction grating 121 and the emitting angle (diffraction angle) φₒᵤₜ of the first-order diffracted light in the second transmission type volume hologram diffraction grating 122 are equal, and the emitting angle (diffraction angle) φₒᵤₜ of the first-order diffracted light in the first transmission type volume hologram diffraction grating 121 and the incident angle φᵢₙ of the first-order diffracted light in the second transmission type volume hologram diffraction grating 122 are equal.

Further, in the first dispersion compensation optical apparatus 120A of the first embodiment, the laser light is incident on the first transmission type volume hologram diffraction grating 121 to be diffracted and reflected and emitted as the first-order diffracted light. After that, the light is incident on the second transmission type volume hologram diffraction grating 122 to be diffracted and reflected and emitted to the outside of the system as the first-order diffracted light. In the first dispersion compensation optical apparatus 120A, the group velocity dispersion value (dispersion compensation amount) is negative.

On the other hand, in the second dispersion compensation optical apparatus 120B, first and second reflection mirrors 123₁ and 123₂ are further provided. Moreover, a first condensing unit (lens) 124₁ is arranged between the first transmission type volume hologram diffraction grating 121 and the first reflection mirror 123₁, and a second condensing unit (lens) 124₂ is arranged between the second reflection mirror 123₂ and the second transmission type volume hologram diffraction grating 122. The first transmission type volume hologram diffraction grating 121, the first condensing unit (lens) 124₁, and the first reflection mirror 123₁ and the second transmission type volume hologram diffraction grating 122, the second condensing unit (lens) 124₂, and the second reflection mirror 123₂ are spatially symmetrically arranged with respect to a virtual plane face. Further, the laser light emitted from the first transmission type volume hologram diffraction grating 121 collides with the first reflection mirror 123₁ to be reflected and then collides with the second reflection mirror 123₂ to be reflected. As a result, the light is incident on the second transmission type volume hologram diffraction grating 122. The laser light incident on the first transmission type volume hologram diffraction grating 121 and the laser light emitted from the second transmission type volume hologram diffraction grating 122 are nearly parallel to each other.

The control of the group velocity dispersion value of the second dispersion compensation optical apparatus 120B may be performed with a change in the optical distance between the first and second transmission type volume hologram diffraction gratings 121 and 122. Specifically, the optical distance between the first and second transmission type volume hologram diffraction gratings 121 and 122 may be changed with the movement of the first condensing unit 124₁ along the light axis and the movement of the second condensing unit 124₂ along the light axis. Note that the dispersion compensation amount is changed to be positive if the condensing units are moved in a direction so as to be close to the transmission type volume hologram diffraction gratings and changed to be negative if the condensing units are moved in a direction so as to be distant from the transmission type volume hologram diffraction gratings. In the second dispersion compensation optical apparatus 120B, the group velocity dispersion value (dispersion compensation amount) is positive.

In an ideal state, the laser light emitted from the mode synchronous semiconductor laser device 110 is no-chirp laser light as shown in FIG. 2B. Further, the pulse time width of the laser light emitted from the dispersion compensation optical apparatus 120A set to have an appropriate negative group velocity dispersion value is extended, and the down-chirp phenomenon occurs. Then, the laser light is incident on the semiconductor light amplifier 130. The properties of the laser light emitted from the semiconductor light amplifier 130 do not change, and the down-chirp phenomenon occurs. Moreover, the pulse time width of the laser light emitted from the dispersion compensation optical apparatus 120B set to have an appropriate positive group velocity dispersion value is compressed, and the laser light with no chirp is emitted.

As described above, with the appropriate selection of the group velocity dispersion values of the dispersion compensation optical apparatuses 120A and 120B, it is possible to extend/compress the pulse time width of the laser light. More specifically, if the group velocity dispersion value is set to be negative/positive with respect to the laser light pulse indicating the down-chirp phenomenon, it is possible to extend/compress the pulse time width of the laser light. As described above, the control of the group velocity dispersion value may be performed with the change in the distance between the first and second transmission type volume hologram diffraction gratings 121 and 122 in each of the dispersion compensation optical apparatuses 120A and 120B. Note that the laser light incident on the first transmission type volume hologram diffraction grating 121 and the laser light emitted from the second transmission type volume hologram diffracting grating 122 are nearly parallel to each other.

In the first embodiment or each of the second to ninth embodiments that will be described later, the mode synchronous semiconductor laser device 110 has the lamination structure in which the first compound semiconductor layer 30 made of the GaN-based semiconductor and having the first conductive type, the third compound semiconductor layer (active layer) 40 made of the GaN-based compound semiconductor, and the second compound semiconductor layer 50 made of the GaN-based compound semiconductor and having the second conductive type different from the first conductive type are successively laminated one on another.

Further, between a second end face 110B of the mode synchronous semiconductor laser device 110 and the first dispersion compensation optical apparatus 120A, an aspherical convex lens having a focal length of 4.0 mm and serving as a collimating unit 111 for forming the laser light emitted from the mode synchronous semiconductor laser device 110 into a parallel light flux and a partial reflection mirror (also called a partial transmission mirror, a semi-transmission mirror, or a half mirror) 112 are arranged. The first end face 110A of the mode synchronous semiconductor laser device 110 and the partial reflection mirror 112 constitute the outside resonator structure. The laser light emitted from the second end face 110B of the mode synchronous semiconductor laser device 110 collides with the partial reflection mirror 112. As a result, some of the laser light passes through the partial reflection mirror 112 and is incident on the first transmission type volume hologram diffraction grating 121, and the other laser light is returned to the mode synchronous semiconductor laser device 110.

The semiconductor light amplifier 130 has substantially the same configuration and structure as those of the mode synchronous semiconductor laser device 110. The semiconductor light amplifier 130 is different from the mode synchronous semiconductor laser device 110 in that it does not convert a light signal into an electric signal but directly amplifies the light signal in the state of light and that it has a laser structure in which the resonator effect is eliminated to a greater extent and amplifies the incident light with the light gain of the semiconductor amplifier. On the front and rear sides of the semiconductor light amplifier 130, lenses 131 and 132 are arranged.

In the semiconductor laser apparatus assemblies of the first embodiment, a wavelength selection unit 200 is further provided. The wavelength selection unit 200 extracts the desired wavelength component (e.g., short wavelength component) of the laser light output to the outside of the system. The wavelength selection unit 200 specifically includes a band pass filter. Thus, with the elimination of an incoherent light pulse component, a coherent light pulse may be obtained. The band pass filter may be obtained by the lamination of, e.g., a dielectric thin film having a low dielectric constant and a dielectric thin film having a high dielectric constant.

In the first embodiment or each of the second to ninth embodiments that will be described later, the mode synchronous semiconductor laser device 110 has the saturable absorption region. Specifically, the mode synchronous semiconductor laser device 110 includes the bi-section type mode synchronous semiconductor laser device 110 in which the light emitting region and the saturable absorption regions are arranged side by side in the resonator direction. More specifically, as shown in FIGS. 9 and 10, the bi-section type mode synchronous semiconductor laser device 110 having a light emitting wavelength of a 405 nm band includes

(a) the lamination structure in which the first compound semiconductor layer 30 having the first conductive type (specifically, the n type conductive type in each of the embodiments) and made of the GaN-based compound semiconductor, the third compound semiconductor layer (active layer) 40 constituting a light emitting region (gain region) 41 made of the GaN-based compound semiconductor and a saturable absorption region 42, and the second compound semiconductor layer 50 having the second conductive type (specifically, the p type conductive type in each of the embodiments) different from the first conductive type and made of the GaN-based compound semiconductor are successively laminated one on another,

(b) a stripe-shaped second electrode 62 formed on the second compound semiconductor layer 50, and

(c) a first electrode 61 electrically connected to the first compound semiconductor layer 30.

Specifically, the mode synchronous semiconductor laser device 110 of the first embodiment or each of the second to ninth embodiments that will be described later is the semiconductor laser device having the ridge stripe type separate confinement heterostructure (SCH structure). More specifically, the mode synchronous semiconductor laser device 110 is the GaN-based semiconductor laser device made of an index guide type AlGaInN and has the ridge stripe structure. Further, the first compound semiconductor layer 30, the third compound semiconductor layer 40, and the second compound semiconductor layer 50 are specifically made of the AlGaInN-based compound semiconductor and more specifically have the layer configuration shown in the following table 2. In table 2, compound semiconductor layers on the lower side are closer to an n type GaN substrate 21. The band gap of a compound semiconductor constituting the well layer of the third compound semiconductor layer 40 is 3.06 eV. The mode synchronous semiconductor laser device 110 of the first embodiment or each of the second to eighth embodiment that will be described later is provided on the (0001) face of the n type GaN substrate 21, and the third compound semiconductor layer 40 has the quantum well structure. The (0001) face of the n type GaN substrate 21 is also called a “C face” and is a crystal plane having polarity.

TABLE 2

| | |
|---|---|
| Second compound semi- | p type GaN contact layer (Mg-doped) 54 |
| conductor layer 50 | p type GaN (Mg-doped)/AlGaN superlattice |
| | cladding layer 53 |
| | p type AlGaN electron barrier layer (Mg- |
| | doped) 52 |
| | non-doped GaInN light guide layer 51 |
| Third compound semi- | GaInN quantum well active layer |
| conductor layer 40 | (well layer: Ga_{0.92}In_{0.08}N/barrier layer: |
| | Ga_{0.98}In_{0.02}N) |
| First compound semi- | n type GaN cladding layer 32 |
| conductor layer 30 | N type AlGaN cladding layer 31 |

(Note)
Well layer (two layers) 8 nm non-doped
Barrier layer (three layers) 14 nm Si-doped

In addition, some of the p type GaN contact layer 54 and the p type GaN/AlGaN superlattice cladding layer 53 is removed by a RIE method to form a ridge stripe structure 55. On both sides of the ridge stripe structure 55, a lamination insulation film 56 made of SiO₂/Si is formed. Note that the SiO₂ layer is a lower layer, and the Si layer is an upper layer. Here, the difference between the effective refractive index of the ridge stripe structure 55 and that of the lamination insulation film 56 is in the range of 5×10⁻³ to 1×10⁻² and specifically 7×10⁻³. Further, on the p type GaN contact layer 54 serving as the top face of the ridge stripe structure 55, the second electrode (p side ohmic electrode) 62 is formed. On the other hand, on the rear face of the n type GaN substrate 21, the first electrode (n side ohmic electrode) 61 made of Ti/Pt/Au is formed.

In the mode synchronous semiconductor laser device 110 of the first embodiment or each of the second to ninth embodiment that will be described later, it is so arranged that the p type AlGaN electron barrier layer 52, the p type GaN/AlGaN superlattice cladding layer 53, and the p type GaN contact layer 54 serving as Mg-doped compound semiconductor layers are not overlapped with the density distribution of the light generated from the third compound semiconductor layer 40 and an area near the third compound semiconductor layer 40 to a greater extent. In this manner, internal loss is prevented unless internal quantum efficiency is reduced. Thus, a threshold current density at which laser oscillation is started is reduced. Specifically, a distance d from the third compound semiconductor layer 40 to the p type AlGaN electron barrier layer 52 is set to 0.10 μm, the height of the ridge stripe structure 55 is set to 0.30 μm, the thickness of the second compound semiconductor layer 50 positioned between the second electrode 62 and the third compound semiconductor layer 40 is set to 0.50 μm, and the thickness of the p type GaN/AlGaN superlattice cladding layer 53 positioned beneath the second electrode 62 is set to 0.40 μm. In addition, the ridge stripe structure 55 is curved toward the second end face to reduce end face reflection, but the shape of the ridge stripe structure 55 is not limited to such a shape.

Further, in the mode synchronous semiconductor laser device 110 of the first embodiment or each of the second to ninth embodiments that will be described later, the second electrode 62 is separated by a separation groove 62C into a first part 62A where direct current is fed to the first electrode 61 via the light emitting region (gain region) 41 to produce a forward bias state and a second part 62B where an electric field is applied to the saturable absorption region 42 (second part 62B where reverse bias voltage Vₛₐ is applied to the saturable absorption region 42). Here, the electric resistance value (also called the “separation resistance value”) between the first and second parts 62A and 62B of the second electrode 62 is 1×10 times or more and specifically 1.5×10³ times as large as the electric resistance value between the first and second electrodes 61 and 62. In addition, the electric resistance value (separation resistance value) between the first and second parts 62A and 62B of the second electrode 62 is 1×10²Ω or more and specifically 1.5×10⁴Ω. The resonator length of the mode synchronous semiconductor laser device 110 is set to 600 μm, and the lengths of the first part 62A, the second part 62B, and the separation groove 62C of the second electrode 62 are set to 560 μm, 30 μm, and 10 μm, respectively. In addition, the width of the ridge stripe structure 55 is set to 1.4 μm.

In the mode synchronous semiconductor laser device 110 of the first embodiment or each of the second to ninth embodiments that will be described later, a non-reflection coating layer (AR) is formed on the light emitting end face (second end face) 110B facing the collimating unit 111. On the other hand, in the mode synchronous semiconductor laser device 110, a high reflection coating layer (HR) is formed on the end face (first end face) 110A facing the light emitting end face (second end face) 110B. The saturable absorption region 42 is provided on the side of the first end face 110A in the mode synchronous semiconductor laser device 110. Examples of the non-reflection coating layer (low reflection coating layer) may include the lamination structure of at least two types of layers selected from the group including a titanium oxide layer, a tantalum oxide layer, a zirconia oxide layer, a silicon oxide layer, and an aluminum oxide layer.

The pulse repetition frequency of the mode synchronous semiconductor laser device 110 of the first embodiment or each of the second to ninth embodiments is set to 1 GHz. Note that the repetition frequency f of a light pulse train is determined by the outside resonator length X′ (distance between the first end face 110A and the partial reflection mirror 112), which is expressed by the following formula. Here, C₀ indicates a light speed, and n indicates the effective refractive index of the resonator.

f=C₀/(2n·X′)

Meanwhile, as described above, the second electrode 62 having a separation resistance value of 1×10²Ω or more is desirably formed on the second compound semiconductor layer 50. In the case of the GaN-based semiconductor laser device, the mobility of the compound semiconductor having the p type conductive type is small unlike a known GaAs-based semiconductor laser device. Therefore, the second electrode 62 formed on the second compound semiconductor layer 50 is separated by the separation groove 62C instead of increasing the resistance of the second compound semiconductor layer 50 having the p type conductive type with the implantation of ion or the like. Thus, it is possible to set the electric resistance value between the first and second parts 62A and 62B of the second electrode 62 to be 10 times or more as large as the electric resistance value between the first and second electrodes 61 and 62 or set the electric resistance value between the first and second parts 62A and 62B of the second electrode 62 to be 1×10²Ω or more.

Here, the second electrode 62 is desired to have the following characteristics.

(1) The second electrode 62 serves as an etching mask for etching the second compound semiconductor layer 50.

(2) The second electrode 62 is capable of being wet-etched without causing the degradation of optical and electrical characteristics in the second compound semiconductor layer 50.

(3) The second electrode 62 shows a contact specific resistance value of 10⁻² Ω·cm² or less when deposited on the second compound semiconductor layer 50.

(4) If the second electrode 62 has the lamination structure, a material constituting the lower metal layer has a large work function, shows a low contact specific resistance value with respect to the second compound semiconductor layer 50, and is capable of being wet-etched.

(5) If the second electrode 62 has the lamination structure, a material constituting the upper metal layer is resistant to etching (e.g., a Cl₂ gas used for a RIE method) for forming the ridge stripe structure and capable of being wet-etched.

In the first embodiment or each of the second to ninth embodiments that will be described later, the second electrode 62 is made of a Pd monolayer having a thickness of 0.1 μm.

Note that the thickness of the p type GaN/AlGaN superlattice cladding layer 53 having the superlattice structure in which the p type GaN layers and the p type AlGaN layers are alternately laminated one on another is 0.7 μm or less and specifically 0.4 μm. The thickness of the p type GaN layers constituting the superlattice structure is 2.5 nm, the thickness of the p type AlGaN layers constituting the superlattice structure is 2.5 nm, and the total number of the p type GaN layers and the p type AlGaN layers is 160. In addition, a distance from the third compound semiconductor layer 40 to the second electrode 62 is 1 μm or less and specifically 0.5 μm. Moreover, the p type AlGaN electron barrier layer 52, the p type GaN/AlGaN superlattice cladding layer 53, and the p type GaN contact layer 54 constituting the second compound semiconductor layer 50 are doped with Mg by 1×10¹⁹ cm⁻³ or more (specifically, 2×10¹⁹ cm⁻³). The absorption coefficient of the second compound semiconductor layer 50 with respect to light having a wavelength of 405 nm is at least 50 cm⁻¹ and specifically 65 cm⁻¹. In addition, although the second compound semiconductor layer 50 has the non-doped compound semiconductor layers (non-doped GaInN light guide layer 51 and the p type compound semiconductor layer) from the side of the third compound semiconductor layer, the distance (d) from the third compound semiconductor layer 40 to the p type compound semiconductor layer (specifically, the p type AlGaN electron barrier layer 52) is 1.2×10⁻⁷ m or less and specifically 100 nm.

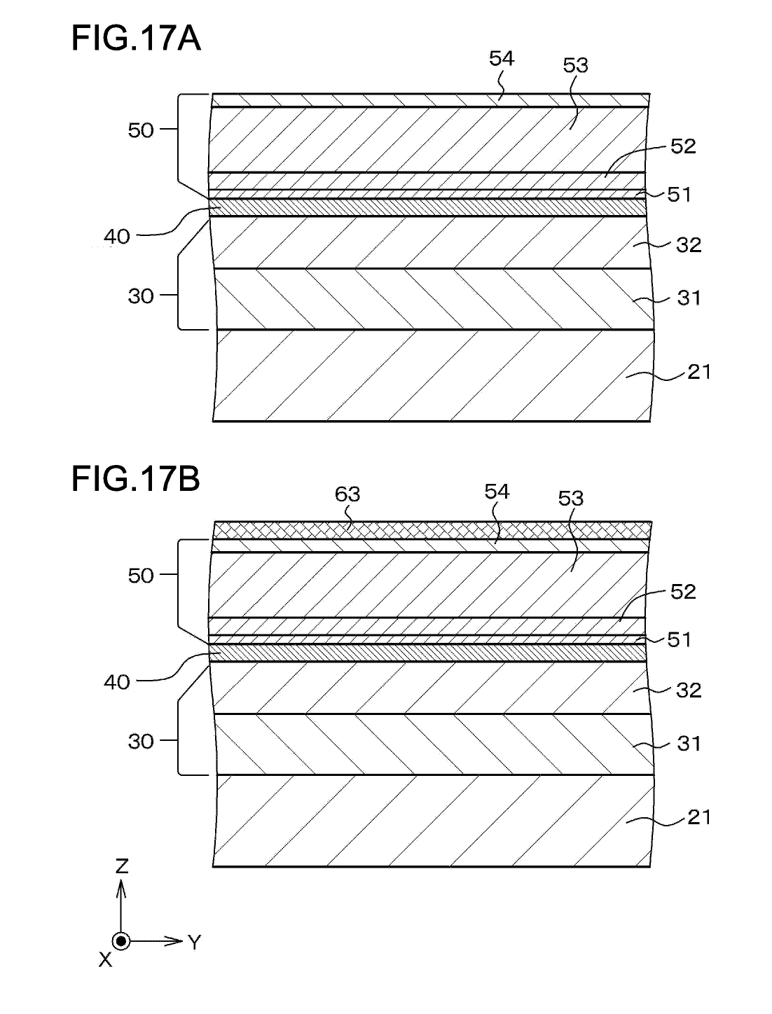

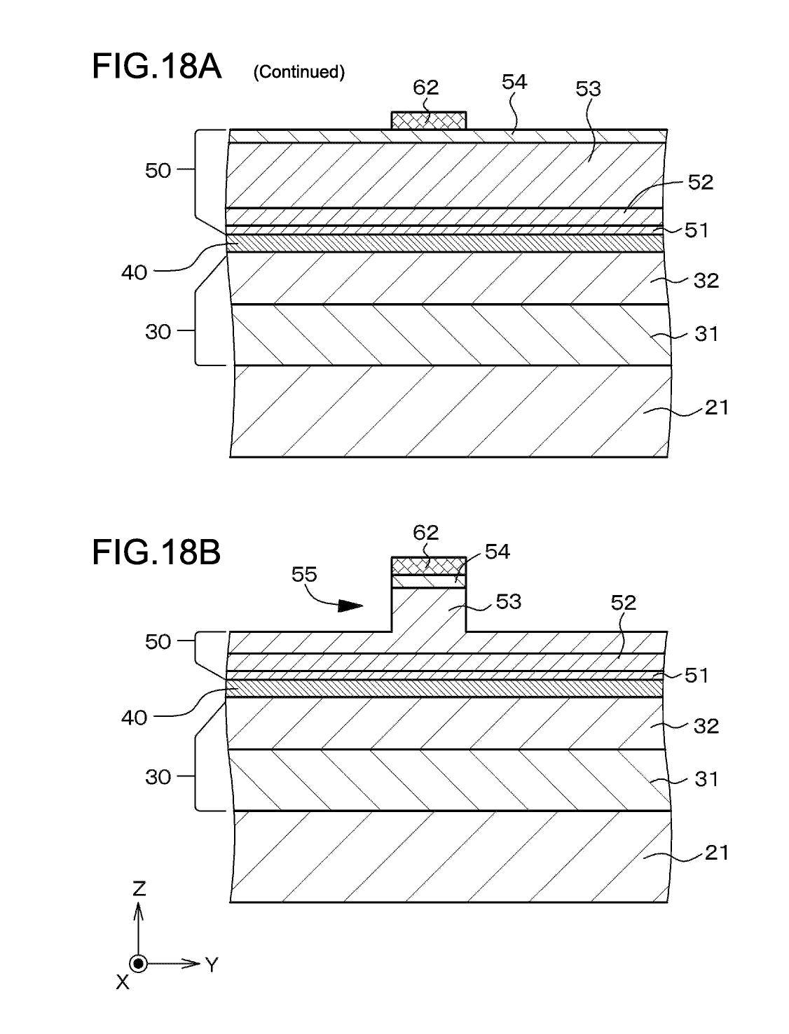

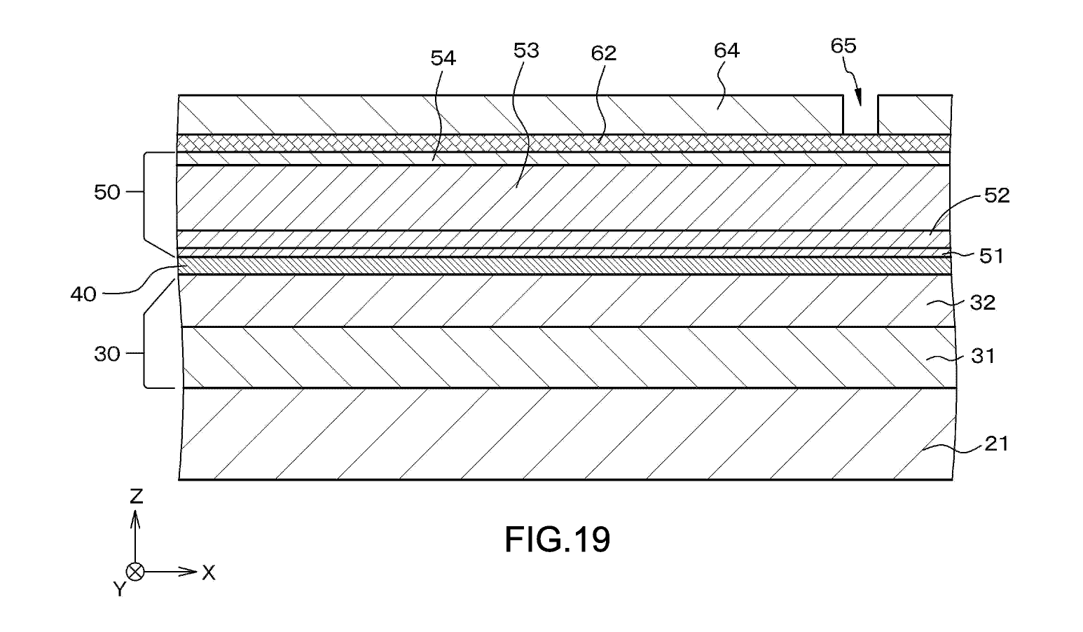

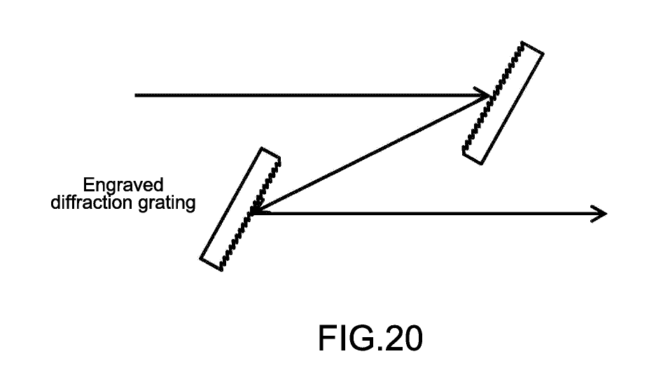

Hereinafter, referring to FIGS. 17A, 17B, 18A, 18B, and 19, a description will be given of a method for manufacturing the mode synchronous semiconductor laser device of the first embodiment or each of the second to ninth embodiments that will be described later. Note that FIGS. 17A, 17B, 18A, and 18B are schematic partial cross-sectional diagrams of a substrate or the like cut out along an YZ plane, and FIG. 19 is a schematic partial end face diagram of the substrate or the like cut out along an XZ plane. Note that the semiconductor light amplifier 130 may be manufactured in the same manner.

(Step 100)

First, based on a known MOCVD method, the lamination structure is formed on the substrate, specifically on the (0001) face of the n type GaN substrate 21, in which the first compound semiconductor layer 30 having the first conductive type (n type conductive type) and made of the GaN-based compound semiconductor, the third compound semiconductor layer (active layer 40) constituting the light emitting region (gain region) 41 and the saturable absorption region 42 made of the GaN-based compound semiconductor, and the second compound semiconductor layer 50 having the second conductive type (p type conductive type) different from the first conductive type and made of the GaN-based compound semiconductor are successively laminated one on another (see FIG. 17A).

(Step 110)

Then, the stripe-shaped second electrode 62 is formed on the second compound semiconductor layer 50. Specifically, after a Pd layer 63 is deposited on the entire face according to a vacuum deposition method (see FIG. 17B), a stripe-shaped etching resist layer is formed on the Pd layer 63 based on photolithography. Subsequently, the Pd layer 63 not covered with the etching resist layer is removed using aqua regia, and then the etching resist layer is removed. Thus, the structure shown in FIG. 18A may be obtained. Note that the stripe-shaped second electrode 62 may be formed on the second compound semiconductor layer 50 based on a lift off method.

(Step 120)

Next, at least part of the second compound semiconductor layer 50 is etched using the second electrode 62 as an etching mask (specifically, part of the second compound semiconductor layer 50 is etched) to form the ridge stripe structure. Specifically, according to a RIE method using a Cl₂ gas, part of the second compound semiconductor layer 50 is etched using the second electrode 62 as the etching mask. Thus, the structure shown in FIG. 18B may be obtained. Since the ridge stripe structure is formed according to a self alignment method using the stripe-shaped-patterned second electrode 62 as the etching mask, no positional deviation occurs between the second electrode 62 and the ridge stripe structure.

(Step 130)

Then, a resist layer 64 for forming the separation groove in the second electrode 62 is formed (see FIG. 19). Note that a reference numeral 65 indicates an opening part provided in the resist layer 64 to form the separation groove. Next, the separation groove 62C is formed in the second electrode 62 according to the wet etching method using the resist layer 64 as a wet etching mask, whereby the second electrode 62 is separated by the separation groove 62C into the first and second parts 62A and 62B. Specifically, the second electrode 62 is entirely soaked in the aqua regia serving as etching liquid for about 10 seconds. As a result, the separation groove 62C is formed in the second electrode 62. After that, the resist layer 64 may be removed. Thus, the structure shown in FIGS. 9 and 10 may be obtained. Accordingly, with the employment of the wet etching method rather than a dry etching method, the degradation of optical and electrical characteristics in the second compound semiconductor layer 50 is not caused. Therefore, no degradation is caused in the light emitting characteristics of the mode synchronous semiconductor laser device. Note that with the employment of the dry etching method, the internal loss a, of the second compound semiconductor layer 50 is increased, which may result in an increase in threshold voltage and a reduction in light output. Here, assuming that the etching rate of the second electrode 62 is ER₀ and that of the lamination structure is ER₁, the relational expression ER₀/ER₁≈1×10² is established. As described above, there is a high etching selection ratio between the second electrode 62 and the second compound semiconductor layer 50. Therefore, the second electrode 62 may be reliably etched without etching the lamination structure (or the lamination structure is slightly etched). Note that it is desirable to satisfy the relational expression ER₀/ER₁≧1×10 and desirably the relational expression ER₀/ER₁≧1×10².

The second electrode may have the lamination structure of the lower metal layer made of palladium (Pd) having a thickness of 20 nm and the upper metal layer made of nickel (Ni) having a thickness of 200 nm. Here, under the wet etching using the aqua regia, the etching rate of the nickel is about 1.25 times as large as the etching rate of the palladium.

(Step 140)

After that, with the formation of an n side electrode, cleavage or the like of the substrate, and packaging, the mode synchronous semiconductor laser device 110 may be manufactured.

The electric resistance value between the second parts 62A and 62B of the second electrode 62 of the manufactured mode synchronous semiconductor laser device 110 is measured according to a four-terminal method. The result of the measurement shows that the electric resistance value between the first and second parts 62A and 62B of the second electrode 62 is 15 kΩ if the width of the separation groove 62C is 20 μm. In addition, in the manufactured mode synchronous semiconductor laser device 110, direct current is fed from the first part 62A of the second electrode 62 to the first electrode 61 via the light emitting region 41 to produce a forward bias state, and reverse bias voltage Vₛₐ is applied between the first electrode 61 and the second part 62B of the second electrode 62 to apply an electric field to the saturable absorption region 42. As a result, a self-pulsation operation may be obtained. In other words, the electric resistance value between the first and second parts 62A and 62B of the second electrode 62 is 10 times or more as large as the electric resistance value between the first and second electrodes 61 and 62 or is 1×10²Ω or more. Accordingly, the leakage of current from the first part 62A to the second part 62B of the second electrode 62 may be reliably reduced. As a result, it is possible to bring the light emitting region 41 into a forward bias state, reliably bring the saturable absorption region 42 into a reverse bias state, and reliably obtain a single mode self-pulsation operation.

In the dispersion compensation optical apparatus of the first embodiment, the sum of the incident angle φᵢₙ of the laser light and the emitting angle φₒᵤₜ of the first-order diffracted light is 90°. Therefore, it is possible to provide the small dispersion compensation optical apparatus that achieves a high throughput with high diffraction efficiency. In addition, since the size of the dispersion compensation optical apparatus is reduced, there is a high degree of flexibility in the arrangement of optical components constituting the dispersion compensation optical apparatus. Moreover, the dependence of the angular dispersion with respect to the wavelength given by formula (8) may be increased. In addition, because the diffraction angle may be arbitrarily set, the degree of flexibility in the optical design of the dispersion compensation optical apparatus may be increased, the adjustment of the group velocity dispersion value (dispersion compensation amount) of the dispersion compensation optical apparatus is facilitated, and the high degree of flexibility in the arrangement of the optical components constituting the dispersion compensation optical apparatus may be achieved.

### Second Embodiment

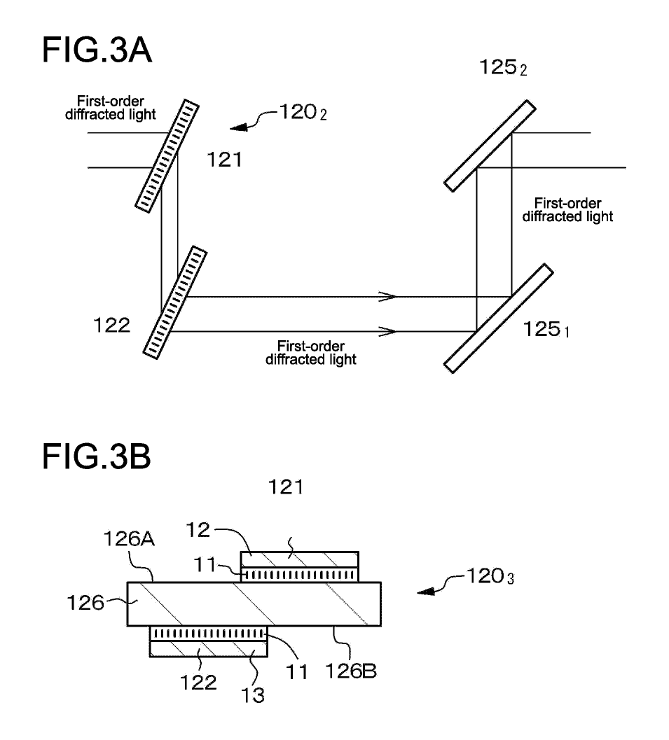

The second embodiment is a modification of the first embodiment and relates to the dispersion compensation optical apparatus or the like of the present disclosure (B). A dispersion compensation optical apparatus 120₂ of the second embodiment, whose conceptual diagram is shown in FIG. 3A, constitutes the first and second dispersion compensation optical apparatuses 120A and 120B of the semiconductor laser apparatus assembly and further includes first and second reflection mirrors 125₁ and 125₂ arranged parallel to each other. Further, the laser light emitted from the second transmission type volume hologram diffraction grating 122 collides with the first reflection mirror 125₁ to be reflected and then collides with the second reflection mirror 125₂ to be reflected. Here, the laser light reflected by the second reflection mirror 125₂ is nearly positioned on the extended line of the laser light incident on the first transmission type volume hologram diffraction grating 121. Thus, the arrangement and insertion of the dispersion compensation optical apparatus 120₂ in an existing optical system is facilitated. Note that if the distance between the first and second transmission type volume hologram diffraction gratings 121 and 122 is adjusted, it is only desired to move the second transmission type volume hologram diffraction grating 122 and the first reflection mirror 125₁ so as not to change the positional relationship between the second transmission type volume hologram diffraction grating 122 and the first reflection mirror 125₁. In the dispersion compensation optical apparatus 120₂, the dispersion compensation amount is negative and depends on the properties on the chirp of the laser light, but the pulse time width of the laser light is, e.g., extended.

Because the dispersion compensation optical apparatus of the second embodiment has the same configuration and structure as those of the dispersion compensation optical apparatus of the first embodiment except for the above points and the semiconductor laser apparatus assembly of the second embodiment has the same configuration and structure as those of the semiconductor laser apparatus assembly of the first embodiment, their detailed description will be omitted.

### Third Embodiment

The third embodiment is also a modification of the first embodiment and relates to the dispersion compensation optical apparatus or the like of the present disclosure (D). A dispersion compensation optical apparatus 120₃ of the third embodiment, whose conceptual diagram is shown in FIG. 3B, constitutes the first and second dispersion compensation optical apparatuses 120A and 120B of the semiconductor laser apparatus assembly. In the dispersion compensation optical apparatus 120₃, the first transmission type volume hologram diffraction grating 121 is provided on a first face 126A of a substrate 126 made of glass, and the second transmission type volume hologram diffraction grating 122 is provided on a second face 126B of the substrate 126 facing the first face 126A. If the distance between the two transmission type volume hologram diffraction gratings 121 and 122 is changed in the dispersion compensation optical apparatus 120₃ of the third embodiment, it is only desired to change the thickness of the substrate 126. Thus, the group velocity dispersion value may be changed. Note that the group velocity dispersion value is negative. The laser light incident on the first transmission type volume hologram diffraction grating 121 and the laser light emitted from the second transmission type volume hologram diffraction grating 122 are nearly parallel to each other.

Because the dispersion compensation optical apparatus of the third embodiment has the same configuration and structure as those of the dispersion compensation optical apparatus of the first embodiment except for the above points and the semiconductor laser apparatus assembly of the third embodiment has the same configuration and structure as those of the semiconductor laser apparatus assembly of the first embodiment, their detailed description will be omitted.

### Fourth Embodiment

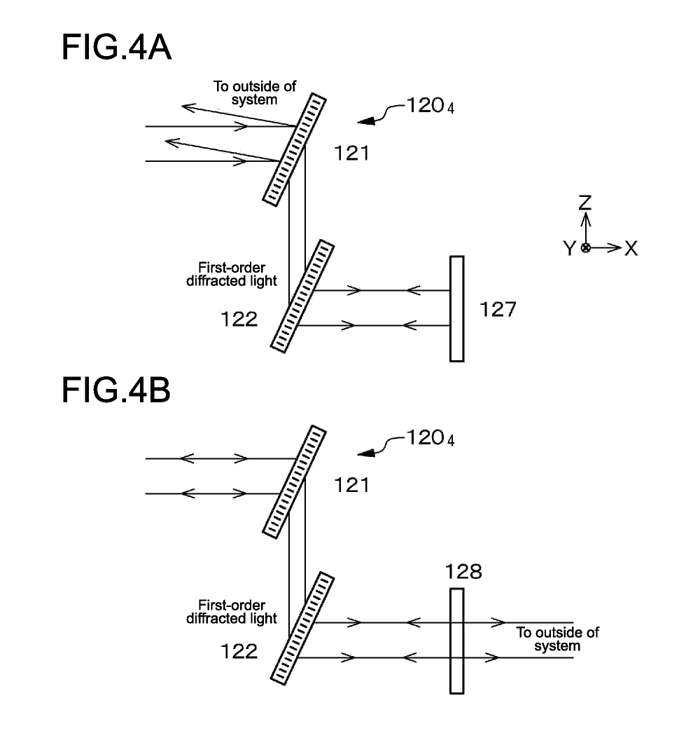

The fourth embodiment is also a modification of the first embodiment and relates to the dispersion compensation optical apparatus or the like of the present disclosure (E). The dispersion compensation optical apparatus of the fourth embodiment, whose conceptual diagram is shown in FIG. 4A, constitutes the first dispersion compensation optical apparatus 120A of the semiconductor laser apparatus assembly and further includes a reflection mirror 127. Further, the laser light is incident on the first transmission type volume hologram diffraction grating 121 to be diffracted and reflected and emitted as the first-order diffracted light. Next, the light is incident on the second transmission type volume hologram diffraction grating 122 to be diffracted and reflected and emitted as the first-order diffracted light. Then, the light collides with the reflection mirror 127. After reflected by the reflection mirror 127, the laser light is incident on the second transmission type volume hologram diffraction grating 122 again to be diffracted and reflected and emitted as the first-order diffracted light. Moreover, the light is incident on the first transmission type volume hologram diffraction grating 121 again to be diffracted and reflected and emitted to the outside of the system (specifically, to the semiconductor light amplifier 130). In order to emit the laser light from the first transmission type volume hologram diffraction grating 121 to the outside of the system, it is only desired to slightly incline the angle of the reflection mirror 127 in a direction orthogonal to the diffraction direction. In other words, it is only desired to slightly rotate the angle of the reflection mirror 127 about a Z axis in FIG. 4A. Thus, it is possible to spatially separate the incident light and the emitting light one from the other. The same applies to the seventh embodiment that will be described later. The control of the group velocity dispersion value may be performed with a change in the distance between the first and second transmission type volume hologram diffraction gratings 121 and 122 in each of the dispersion compensation optical apparatuses 120A and 120B. The group velocity dispersion value is negative. Note that the control of the group velocity dispersion value may also be performed with a change in the distance between the second transmission type volume hologram diffraction grating 122 and the condensing unit in a state in which the condensing unit (lens) is arranged between the second transmission type volume hologram diffraction grating 122 and the reflection mirror 127 and the distance between the reflection mirror 127 and the condensing unit is fixed.

Note that as shown in the conceptual diagram of FIG. 4B, a partial reflection mirror 128 may be arranged instead of the reflection mirror 127. In this configuration, the laser light is incident on the first transmission type volume hologram diffraction grating 121 to be diffracted and reflected and emitted as the first-order diffracted light. Next, the light is incident on the second transmission type volume hologram diffraction grating 122 to be diffracted and reflected and emitted as the first-order diffracted light. After emitted from the second transmission type volume hologram diffraction grating 122, the light collides with the partial reflection mirror 128. Some of the light is emitted to the outside of the system (specifically, to the semiconductor light amplifier 130), and the other light is reflected by the partial reflection mirror 128 and incident on the second transmission type volume hologram diffraction grating 122 again. Then, the light is diffracted and reflected by the second transmission type volume hologram diffraction grating 122 and emitted as the first-order diffracted light. Moreover, the light is incident on the first transmission type volume hologram diffraction grating 121 again to be diffracted and reflected and returned to the mode synchronous semiconductor laser device 110. Note that also in this case, a dispersion compensation optical apparatus 120₄ (more specifically, the partial reflection mirror 128) and the first end face 110A of the mode synchronous semiconductor laser device 110 constitute the outside resonator structure. Therefore, it is not necessary to arrange the partial reflection mirror 112 shown in FIG. 1.

Because the dispersion compensation optical apparatus of the fourth embodiment has the same configuration and structure as those of the dispersion compensation optical apparatus of the first embodiment except for the above points and the semiconductor laser apparatus assembly of the fourth embodiment has the same configuration and structure as those of the semiconductor laser apparatus assembly of the first embodiment, their detailed description will be omitted.

### Fifth Embodiment

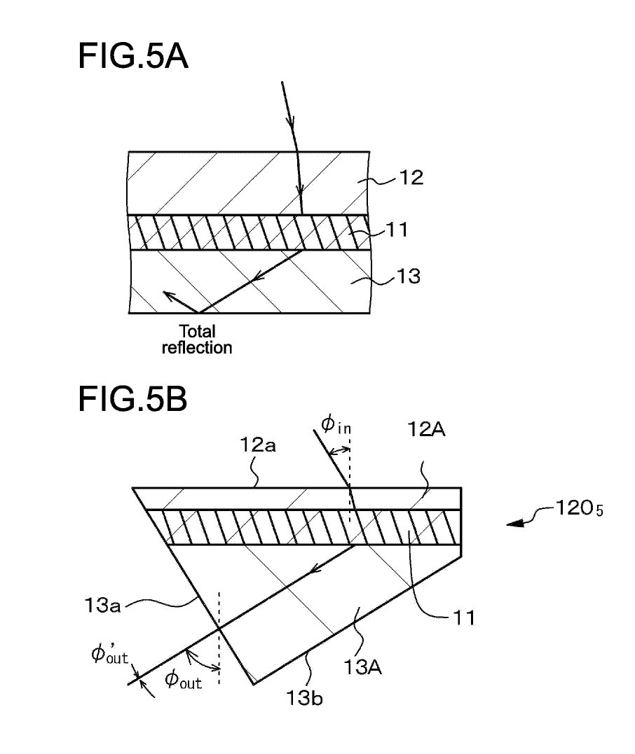

The fifth embodiment is a modification of the first, second, and fourth embodiments. Meanwhile, the practical upper limit of the emitting angle φₒᵤₜ of the first-order diffracted light in the first transmission type volume hologram diffraction grating 121 depends on the condition in which the diffracted light is emitted without being totally reflected by the glass substrate 13. In other words, if the diffracted light is totally reflected inside the glass substrate 13 as shown in FIG. 5A, it is not taken out from the first transmission type volume hologram diffraction grating 121.

According to the fifth embodiment, as shown in the schematic partial cross-sectional diagram of FIG. 5B, a glass substrate 13A on the emitting side constituting the transmission type volume hologram diffraction grating of a dispersion compensation optical apparatus 120₅ of the fifth embodiment is formed into a prism shape having inclined faces 13a and 13b and arranged such that the diffracted light is emitted from the inclined face 13a of the glass substrate 13A. Thus, the diffracted light may not be totally reflected by the glass substrate 13A. Note that a front face 12a of a glass substrate 12A on the incident side constituting the transmission type volume hologram diffraction grating is not parallel to the inclined faces 13a and 13b. The inclination angle of the inclined face 13a is desirably set such that the emitting angle φₒᵤₜ formed by the normal line of the inclined face 13a and the first-order diffracted light becomes, e.g., 0°±10°.

Because the dispersion compensation optical apparatus of the fifth embodiment has the same configuration and structure as those of the dispersion compensation optical apparatuses of the first, second and fourth embodiment except for the above points and the semiconductor laser apparatus assembly of the fifth embodiment has the same configuration and structure as those of the semiconductor laser apparatus assembly of the first embodiment, their detailed description will be omitted.

### Sixth Embodiment

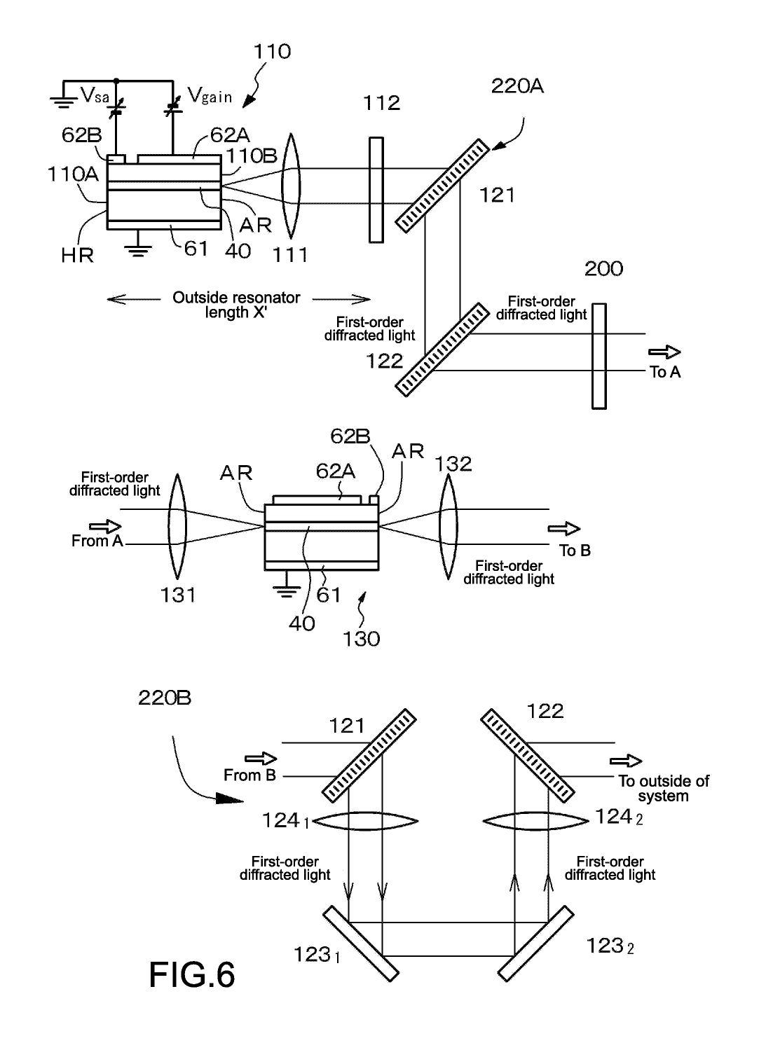

The sixth embodiment relates to the dispersion compensation optical apparatus according to the second mode of the present disclosure. FIG. 6 shows the conceptual diagram of the semiconductor laser apparatus assembly that incorporates the dispersion compensation optical apparatus of the sixth embodiment. Each of first and second dispersion compensation optical apparatuses 220A and 220B of the sixth embodiment includes the two transmission type volume hologram diffraction gratings (first and second transmission type volume hologram diffraction gratings 121 and 122) arranged facing each other. In each of the first and second transmission type volume hologram diffraction gratings 121 and 122, the incident angle φᵢₙ of the laser light and the emitting angle φₒᵤₜ of the first-order diffracted light are substantially equal (specifically equal in the sixth embodiment). In addition, the sum of the incident angle φᵢₙ of the laser light and the emitting angle φₒᵤₜ of the first-order diffracted light is 90°. In other words, the relational expression φᵢₙ=φₒᵤₜ=45° is established.

Except for the above points, the first and second dispersion compensation optical apparatuses 220A and 220B of the sixth embodiment have the same configuration and structure as those of the first and second dispersion compensation optical apparatuses 120A and 120B of the first embodiment. In addition, except for the point in which the relational expression φᵢₙ=φₒᵤₜ=45° is established, the first dispersion compensation optical apparatus 220A of the sixth embodiment may have the same configuration and structure as those of the second to fifth embodiments. Moreover, because the semiconductor laser apparatus assembly of the sixth embodiment has the same configuration and structure as those of the semiconductor laser apparatus assembly of the first embodiment, their detailed description will be omitted. Note that the group velocity dispersion value is negative in the first dispersion compensation optical apparatus 220A and is positive in the second dispersion compensation optical apparatus 220B.

In the dispersion compensation optical apparatus of the sixth embodiment, the incident angle φᵢₙ of the laser light and the emitting angle φₒᵤₜ of the first-order diffracted light are substantially equal. Therefore, it is possible to provide the small dispersion compensation optical apparatus that achieves a high throughput with high diffraction efficiency. In addition, since the size of the dispersion compensation optical apparatus is reduced, there is a high degree of flexibility in the arrangement of optical components constituting the dispersion compensation optical apparatus. Moreover, because the diffraction angle may be arbitrarily set, the degree of flexibility in the optical design of the dispersion compensation optical apparatus may be increased, the adjustment of the group velocity dispersion value (dispersion compensation amount) of the dispersion compensation optical apparatus is facilitated, and the high degree of flexibility in the arrangement of the optical components constituting the dispersion compensation optical apparatus may be achieved.

### Seventh Embodiment

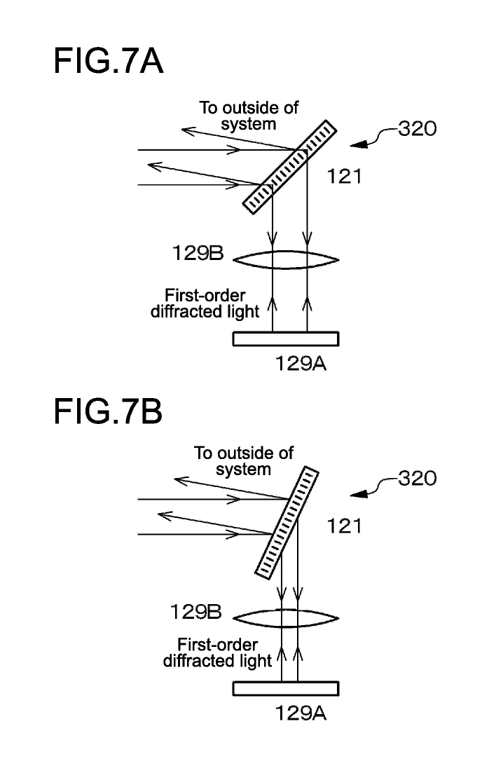

The seventh embodiment relates to the dispersion compensation optical apparatus according to the third mode of the present disclosure. FIG. 7A shows the conceptual diagram of a dispersion compensation optical apparatus 320 of the seventh embodiment. The dispersion compensation optical apparatus 320 of the seventh embodiment constitutes the first dispersion compensation optical apparatus of the semiconductor laser apparatus assembly and includes the transmission type volume hologram diffraction grating 121 and a reflection mirror 129A. In the transmission type volume hologram diffraction grating 121, the incident angle φᵢₙ of the laser light and the emitting angle φₒᵤₜ of the first-order diffracted light are substantially equal (specifically equal in the seventh embodiment). The laser light emitted from the mode synchronous semiconductor laser device 110 is incident on the transmission type volume hologram diffraction grating 121 to be diffracted and emitted as the first-order diffracted light. Then, the first-order diffracted light collides with the reflection mirror 129A to be reflected. After reflected by the reflection mirror 129A, the first-order diffracted light is incident on the transmission type volume hologram diffraction grating 121 again to be diffracted and emitted to the outside of the system.

In addition, as shown in the conceptual diagram of FIG. 7B, the dispersion compensation optical apparatus 320 of the seventh embodiment includes the transmission type volume hologram diffraction grating 121 and the reflection mirror 129A. In the transmission type volume hologram diffraction grating 121, the sum of the incident angle φᵢₙ of the laser light and the emitting angle φₒᵤₜ of the first-order diffracted light is 90°.

The laser light emitted from the mode synchronous semiconductor laser device 110 is incident on the transmission type volume hologram diffraction grating 121 to be diffracted and emitted as the first-order diffracted light. Then, the first-order diffracted light collides with the reflection mirror 129A to be reflected. After reflected by the reflection mirror 129A, the first-order diffracted light is incident on the transmission type volume hologram diffraction grating 121 again to be diffracted and emitted to the outside of the system.

Further, a condensing unit (lens) 129B is arranged between the transmission type volume hologram diffraction grating 121 and the reflection mirror 129A. The group velocity dispersion value (dispersion compensation amount) is changed with a change in the distance between the transmission type volume hologram diffraction grating 121 and the reflection mirror 129A. Specifically, the group velocity dispersion value may be changed with the change in the distance between the transmission type volume hologram diffraction grating 121 and the reflection mirror 129A in a state in which the distance between the condensing unit 129B and the reflection mirror 129A is fixed. For example, if the distance between the transmission type volume hologram diffraction grating 121 and the condensing unit 129B and the focal length of the condensing unit 129B are equal, there is no change in the angular dispersion of the laser light directed from the transmission type volume hologram diffraction grating 121 to the condensing unit 129B and that of the laser light reflected by the reflection mirror 129 and incident on the transmission type volume hologram diffraction grating 121 via the condensing unit 129B. Accordingly, in this case, the dispersion compensation amount given by a dispersion compensation optical system is zero. On the other hand, if the distance between the transmission type volume hologram diffraction grating 121 and the condensing unit 129B is larger than the focal length of the condensing unit 129B, the light path of the long wavelength component of the laser light diffracted by the transmission type volume hologram diffraction grating 121 becomes larger than the light path of the short wavelength component. In this case, the negative group velocity dispersion is formed. In other words, the group velocity dispersion value becomes negative. In addition, if the distance between the transmission type volume hologram diffraction grating 121 and the condensing unit 129B is smaller than the focal length of the condensing unit 129B, the group velocity dispersion value becomes positive.

In the dispersion compensation optical apparatus 320 of the seventh embodiment, the dispersion compensation optical apparatus 320 and the first end face 110A of the mode synchronous semiconductor laser device 110 constitute the outside resonator structure.

Because the dispersion compensation optical apparatus of the seventh embodiment has the same configuration and structure as those of the dispersion compensation optical apparatus of the first embodiment except for the above points and the semiconductor laser apparatus assembly of the seventh embodiment has the same configuration and structure as those of the semiconductor laser apparatus assembly of the first embodiment, their detailed description will be omitted.

Since the dispersion compensation optical apparatus of the seventh embodiment includes the transmission type volume hologram diffraction grating 121 and the reflection mirror 129A, it is possible to provide the small dispersion compensation optical apparatus that achieves a high throughput with high diffraction efficiency. In addition, since the size of the dispersion compensation optical apparatus is reduced, there is a high degree of flexibility in the arrangement of optical components constituting the dispersion compensation optical apparatus. Moreover, because the diffraction angle may be arbitrarily set, the degree of flexibility in the optical design of the dispersion compensation optical apparatus may be increased, the adjustment of the group velocity dispersion value (dispersion compensation amount) of the dispersion compensation optical apparatus is facilitated, and the high degree of flexibility in the arrangement of the optical components constituting the dispersion compensation optical apparatus may be achieved.

### Eighth Embodiment

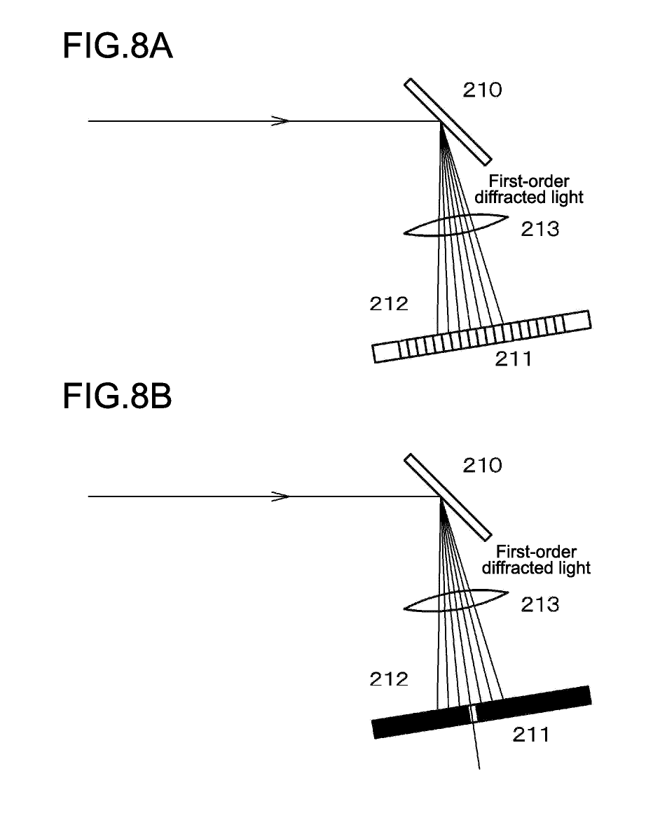

The eighth embodiment is a modification of the first to seventh embodiments. In the eighth embodiment, as shown in the conceptual diagrams of FIGS. 8A and 8B, the wavelength selection unit may include, instead of a band pass filter, a diffraction grating 210 and an aperture 211 that selects the first-order diffracted light emitted from the diffraction grating 210. The aperture 211 includes, e.g., a transmission type liquid crystal display apparatus 212 having a multiplicity of segments. Note that a lens 213 is arranged between the diffraction grating 210 and the aperture 211 constituting the wavelength selection unit.

The wavelength of the laser light emitted from the second transmission type volume hologram diffraction grating 122 has a certain wavelength range. Accordingly, as shown in FIG. 8A, the first-order diffracted light diffracted by the diffraction grating 210 is likely to collide with the aperture 211 at a multiplicity of regions. Note that in FIGS. 8A and 8B, the convergence and diffusion of a light path by the lens 213 are not taken into consideration. Here, as shown in FIG. 8B, only the laser light having a desired wavelength emitted from the second transmission type volume hologram diffraction grating 122 is finally output to the outside in such a manner that the laser light is caused to transmit a desired segment (constituting the aperture 211) of the transmission type liquid crystal display apparatus 212 having the multiplicity of segments. As described above, the wavelength selection may be performed with the selection of the aperture 211. Note that in each of the semiconductor laser apparatus assemblies of the first and sixth embodiments shown in FIGS. 1 and 6, the wavelength selection unit including the aperture 211 may be inserted between the transmission type volume hologram diffraction gratings 121 and 122 constituting the dispersion compensation optical apparatus 120A, or the wavelength selection unit including the aperture 211 may be inserted between the first and second reflection mirrors 123₁ and 123₂ constituting the dispersion compensation optical apparatus 120B.

### Ninth Embodiment

The ninth embodiment is a modification of the mode synchronous semiconductor laser devices described in the first to eighth embodiments and relates to the mode synchronous semiconductor laser device having a third configuration. In each of the first to eighth embodiments, the mode synchronous semiconductor laser device 110 is provided on the (0001) face of the n type GaN substrate 21 serving as a crystal plane having polarity, i.e., the C face. Meanwhile, if such a substrate is used, it may be difficult to electrically control saturable absorption due to the QCSE (Quantum Confinement Stark Effect) of an internal electric field resulting from piezo polarization and spontaneous polarization in the active layer 40. In other words, it turns out that in some cases, the value of direct current fed to the first electrode and the value of reverse bias voltage applied to the saturable absorption region are desirably increased in order to obtain a self pulsation operation and a mode synchronous operation, a sub-pulse component accompanied by a main pulse is generated, and the synchronization between an outside signal and a light pulse becomes difficult.

In order to prevent the occurrence of such phenomena, it turns out that the thickness of the well layer constituting the active layer 40 and the concentration of the doped-impurity of the barrier layer constituting the active layer 40 are desirably optimized.

Specifically, the thickness of the well layer constituting the GaInN quantum well active layer is set to 1 nm or more and 10.0 nm or less and desirably 1 nm or more and 8 nm or less. With a reduction in the thickness of the well layer, the influences of piezo polarization and spontaneous polarization may be reduced. In addition, the concentration of the doped-impurity of the barrier layer is set to 2×10¹⁸ cm⁻³ or more and 1×10²⁰ cm⁻³ or less and desirably 1×10¹⁹ cm⁻³ or more and 1×10²⁰ cm⁻³ or less. Here, examples of the impurity may include silicon (Si) and oxygen (O). Under such a concentration of the doped-impurity of the barrier layer, the carrier of the active layer may be increased. As a result, the influences of piezo polarization and spontaneous polarization may be reduced.

In the ninth embodiment, the active layer 40 including the GaInN quantum well active layer having the three-layered barrier layer (made of Ga_{0.98}In_{0.02}N) and the two-layered well layer (made of Ga_{0.92}In_{0.08}N) in the layer configuration shown in table 3 is configured as follows. In addition, in the mode synchronous semiconductor laser device of a reference example, the active layer 40 in the layer configuration shown in table 2 is configured as follows. Specifically, the active layer 40 has the same configuration as that of the first embodiment.

TABLE 3

| | Ninth Embodiment | Reference Example |
|---|---|---|
| Well layer | 8 nm | 10.5 nm |
| Barrier layer | 12 nm | 14 nm |
| Concentration of doped- | Non-doped | Non-doped |
| impurity of well layer | | |
| Concentration of doped- | Si: 2 × 10¹⁸ cm⁻³ | Non-doped |
| impurity of barrier layer | | |

In the ninth embodiment, the thickness of the well layer is 8 nm, the barrier layer is doped with Si by 2×10¹⁸ cm⁻³, and the QCSE is reduced inside the active layer. On the other hand, in the reference example, the thickness of the well layer is 10.5 nm, and the barrier layer is not doped with an impurity.

As is the case with the first embodiment, mode synchronization is determined by direct current applied to the light emitting region and reverse bias voltage Vₛₐ applied to the saturable absorption region. The reverse bias voltage dependence of the relationship between the input current and the output light (L-I characteristics) of the ninth embodiment and the reference example is measured. It turns out that in the reference example, the threshold current at which laser oscillation is started gradually increases with an increase in the reverse bias voltage Vₛₐ and there occurs a change with the reverse bias voltage Vₛₐ lower than that of the ninth embodiment. It represents that the effect of saturable absorption is electrically controlled by the reverse bias voltage Vₛₐ in the active layer of the ninth embodiment. However, even in the reference example, a self pulsation operation and a mode synchronization (mode locking) operation in a single mode (single fundamental lateral mode) are confirmed in a state in which a reverse bias is applied to the saturable absorption region. Therefore, it is needless to say that the reference example is also included in the present disclosure.

The present disclosure is described above based on the desired embodiments but is not limited to the embodiments. The configurations and structural configurations of the semiconductor laser apparatus assembly, the mode synchronous semiconductor laser device, and the dispersion compensation optical apparatus in each of the embodiments are for exemplary purposes and may be appropriately changed. In addition, the various values of the embodiments are also for exemplary purposes and may be properly changed if the specifications of the used mode synchronous semiconductor laser devices are changed.

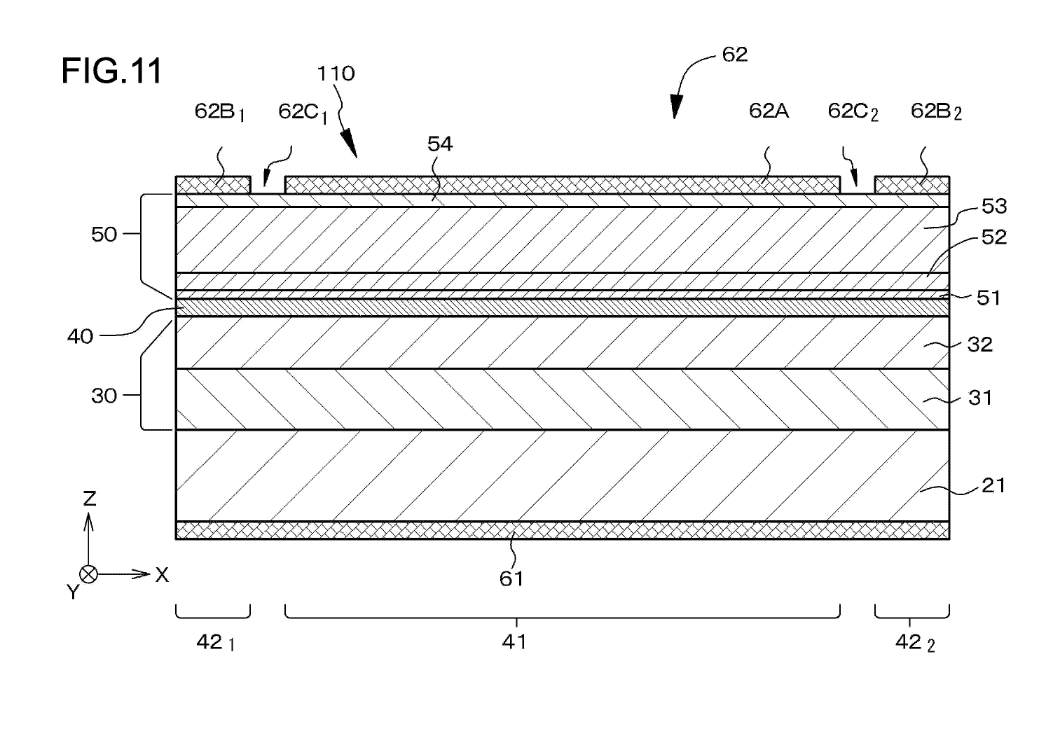

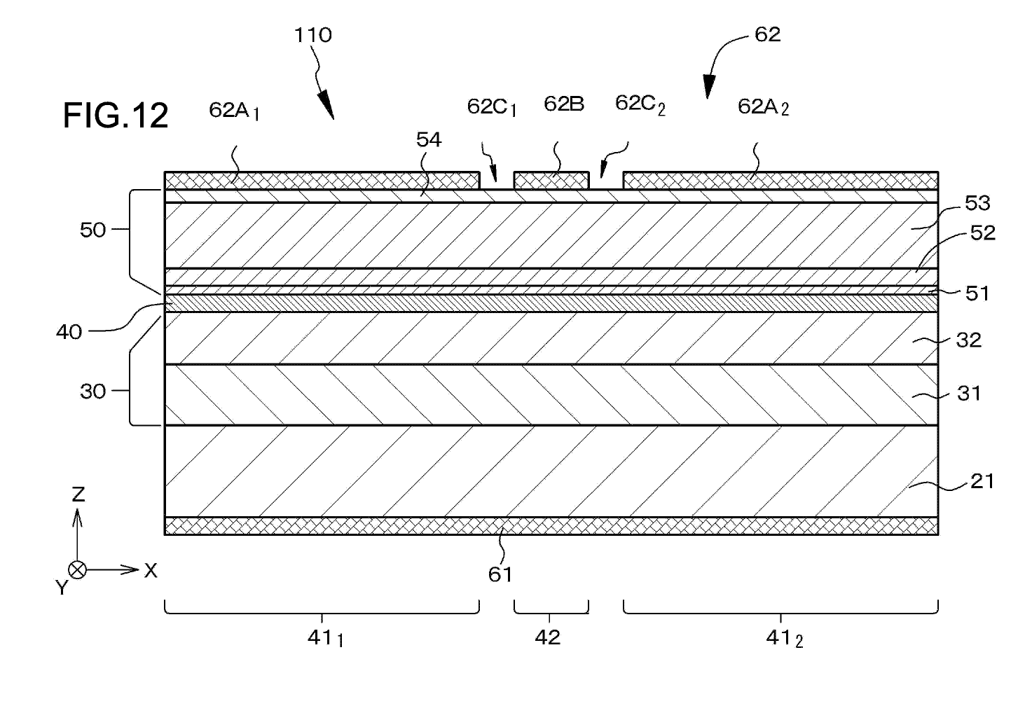

The number of the light emitting regions 41 and the saturable absorption regions 42 is not limited to one. FIGS. 11 and 12 show the schematic end face diagrams of the mode synchronous semiconductor laser devices (multi-section type (multi-electrode type) semiconductor laser devices) in which the one first part 62A of the second electrode and the two second parts 62B₁ and 62B₂ of the second electrode are provided. In the mode synchronous semiconductor laser device shown in FIG. 11, the one end of the first part 62A faces the one second part 62B₁ via one separation groove 62C₁, and the other end of the first part 62A faces the other second part 62B₂ via the other separation groove 62C₂. Further, the one light emitting region 41 is held between two saturable absorption regions 42₁ and 42₂. FIG. 12 shows the schematic end face diagram of the mode synchronous semiconductor laser device in which two first parts 62A₁ and 62A₂ of the second electrode and the one second part 62B of the second electrode are provided. In the mode synchronous semiconductor laser device, the one end of the second part 62B faces the one first part 62A₁ via one separation groove 62C₁, and the other end of the second part 62B faces the other first part 62A₂ via the other separation groove 62C₂. Further, one saturable absorption region 42 is held between two light emitting regions 41₁ and 41₂.

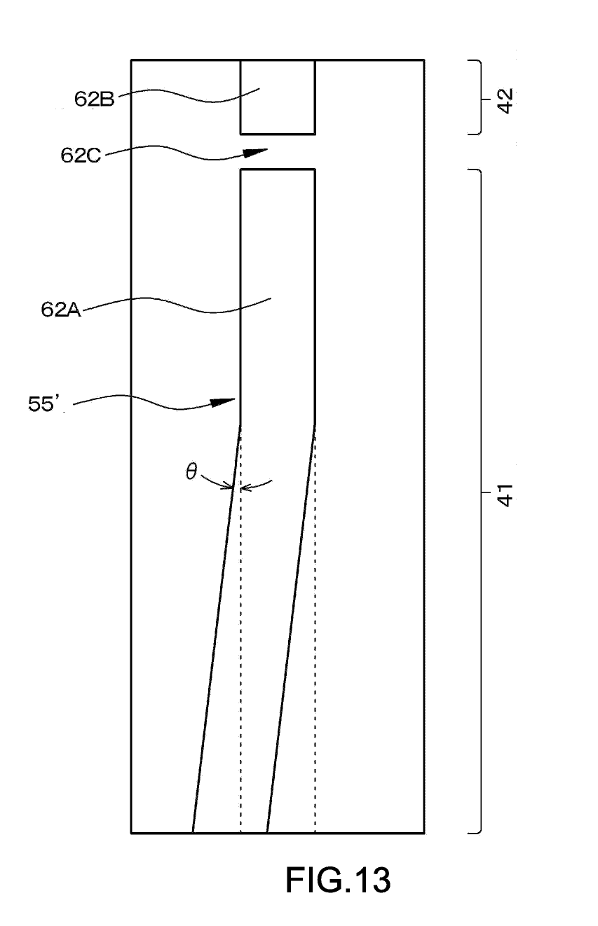

The mode synchronous semiconductor laser device may be the semiconductor laser device of a ridge stripe type separate confinement heterostructure having an oblique waveguide. FIG. 13 shows the schematic diagram of a ridge stripe structure 55′ of such a mode synchronous semiconductor laser device as seen from the above. This mode synchronous semiconductor laser device has a structure in which two linear ridge stripe structures are combined together, and the value of an angle θ at which the two ridge stripe structures cross each other is in the range of e.g., 0°<θ≦10° and desirably in the range of 0°<0≦6°. With the employment of the oblique ridge stripe type, the reflectance of a second end face having non-reflection coating applied thereto may get close to an ideal value of 0% to a greater extent. As a result, the circulation of laser light inside the mode synchronous semiconductor laser device may be prevented, and thus the generation of subsidiary laser light accompanied by main laser light may be reduced.

In each of the embodiments, the mode synchronous semiconductor laser device 110 is provided on the C face serving as the polar face of the n type GaN substrate 21, i.e., the (0001) face. Alternatively, the mode synchronous semiconductor laser device 110 may be provided on non-polar faces such as an A face serving as the (11-20) face, an M face serving as the (1-100) face, and the (1-102) face or may be provided on semi-polar faces such as (11-2n) faces such as the (11-24) face and the (11-22) face, the (10-11) face, and the (10-12) face. Thus, even if piezo polarization and spontaneous polarization occur in the third compound semiconductor layer of the mode synchronous semiconductor laser device 110, the piezo polarization is not generated in the thickness direction of the third compound semiconductor layer but is generated in a direction substantially perpendicular to the thickness direction of the third compound semiconductor layer. As a result, adverse effects resulting from the piezo polarization and spontaneous polarization may be eliminated. Note that the (11-2n) face indicates a non-polar face that forms an angle of approximately 40° with respect to the C face. In addition, if the mode synchronous semiconductor laser device 110 is provided on the non-polar face or the semi-polar face, it is possible to remove the restrictions on the thickness of the well layer (1 nm or more and 10 nm or less) and the concentration of the doped-impurity of the barrier layer (2×10¹⁸ cm⁻³ or more and 1×10²⁰ cm⁻³ or less) described in the ninth embodiment.

Note that the present disclosure may also employ the following configurations.

(1) (Dispersion compensation optical apparatus: first mode)

A dispersion compensation optical apparatus, including:

a first transmission type volume hologram diffraction grating; and

a second transmission type volume hologram diffraction grating, in which

the first and second transmission type volume hologram diffraction gratings are arranged facing each other, and

a sum of an incident angle of laser light and an emitting angle of first-order diffracted light is 90° in each of the first and second transmission type volume hologram diffraction gratings.

(2) The dispersion compensation optical apparatus according to (1), in which

the emitting angle of the first-order diffracted light is larger than the incident angle of the laser light in the first transmission type volume hologram diffraction grating on which the laser light emitted from a semiconductor laser device is incident.

(3) (Dispersion compensation optical apparatus: second mode)

A dispersion compensation optical apparatus, including:

a first transmission type volume hologram diffraction grating; and

a second transmission type volume hologram diffraction grating, in which

the first and second transmission type volume hologram diffraction gratings are arranged facing each other, and

an incident angle of laser light and an emitting angle of first-order diffracted light are substantially equal in each of the first and second transmission type volume hologram diffraction gratings.

(4) The dispersion compensation optical apparatus according to (3), in which

a sum of the incident angle of the laser light and the emitting angle of the first-order diffracted light is 90°.

(5) The dispersion compensation optical apparatus according to any one of (1) to (4), in which

the laser light is incident on the first transmission type volume hologram diffraction grating to be diffracted and emitted as the first-order diffracted light, and

the laser light is then incident on the second transmission type volume hologram diffraction grating to be diffracted and emitted to an outside of a system as the first-order diffracted light.

(6) The dispersion compensation optical apparatus according to (5), further including:

a first reflection mirror; and

a second reflection mirror, in which

the first and second reflection mirrors are arranged parallel to each other, and

the laser light emitted from the second transmission type volume hologram diffraction grating collides with the first reflection mirror to be reflected and then collides with the second reflection mirror to be reflected.

(7) The dispersion compensation optical apparatus according to (6), in which

the laser light reflected by the second reflection mirror is nearly positioned on an extended line of the laser light incident on the first transmission type volume hologram diffraction grating.

(8) The dispersion compensation optical apparatus according to (5), further including:

a first reflection mirror; and

a second reflection mirror, in which

the laser light emitted from the first transmission type volume hologram diffraction grating collides with the first reflection mirror to be reflected, and

the laser light then collides with the second reflection mirror to be reflected and is incident on the second transmission type volume hologram diffraction grating.

(9) The dispersion compensation optical apparatus according to (8), in which

a condensing unit is provided between the first transmission type volume hologram diffraction grating and the first reflection mirror, and

a condensing unit is provided between the second reflection mirror and the second transmission type volume hologram diffraction grating.

(10) The dispersion compensation optical apparatus according to according to any one of (1) to (4), in which

the first transmission type volume hologram diffraction grating is provided on a first face of a substrate, and

the second transmission type volume hologram diffraction grating is provided on a second face of the substrate, the second face facing the first face.

(11) The dispersion compensation optical apparatus according to any one of (1) to (4), further including:

a reflection mirror, in which

the laser light is incident on the first transmission type volume hologram diffraction grating to be diffracted and emitted as the first-order diffracted light,

the laser light is then incident on the second transmission type volume hologram diffraction grating to be diffracted and emitted as the first-order diffracted light to collide with the reflection mirror,

the laser light reflected by the reflection mirror is incident on the second transmission type volume hologram diffraction grating again to be diffracted and emitted as the first-order diffracted light, and

the laser light is incident on the first transmission type volume hologram diffraction grating again to be diffracted and emitted to an outside of a system.

(12) The dispersion compensation optical apparatus according to any one of (1) to (4), further including:

a partial reflection mirror, in which

the laser light is incident on the first transmission type volume hologram diffraction grating to be diffracted and emitted as the first-order diffracted light,

the laser light is then incident on the second transmission type volume hologram diffraction grating to be diffracted and emitted as the first-order diffracted light to collide with the partial reflection mirror, some of the laser light being emitted to an outside of a system, the other laser light being reflected by the partial reflection mirror,

the laser light reflected by the partial reflection mirror is incident on the second transmission type volume hologram diffraction grating again to be diffracted and emitted as the first-order diffracted light, and

the laser light is incident on the first transmission type volume hologram diffraction grating again to be diffracted.

(13) The dispersion compensation optical apparatus according to any one of (1) to (12), in which

a group velocity dispersion value is changed with a change in a distance between the two transmission type volume hologram diffraction gratings.

(14) (Dispersion compensation optical apparatus: third mode)

A dispersion compensation optical apparatus, including:

a transmission type volume hologram diffraction grating; and

a reflection mirror, in which

a sum of an incident angle of laser light and an emitting angle of first-order diffracted light is 90° or the incident angle of the laser light and the emitting angle of the first-order diffracted light are substantially equal in the transmission type volume hologram diffraction grating,

the laser light emitted from a semiconductor laser device is incident on the transmission type volume hologram diffraction grating to be diffracted and emitted as the first-order diffracted light to collide with the reflection mirror, and

the first-order diffracted light reflected by the reflection mirror is incident on the transmission type volume hologram diffraction grating again to be diffracted and emitted to an outside of a system.

(15) The dispersion compensation optical apparatus according to (14), in which

a group velocity dispersion value is changed with a change in a distance between the transmission type volume hologram diffraction grating and the reflection mirror.

(16) The dispersion compensation optical apparatus according to any one of (1) to (15), in which

a semiconductor laser device from which the laser light is emitted includes a mode synchronous semiconductor laser device.

(17) The dispersion compensation optical apparatus according to any one of (1) to (16), in which

the transmission type volume hologram diffraction gratings have a structure in which a diffraction grating member is held between two glass substrates, and

the following formula (A) is satisfied assuming that a wavelength of the laser light incident on the diffraction grating member is λ, a spectrum width of the laser light is Δλ, the incident angle of the laser light incident on the diffraction grating member is θᵢₙ, a diffraction angle is θₒᵤₜ, a refractive index of the glass substrates is N, and a thickness of the diffraction grating member is L.

|{1−cos(θᵢₙ+θₒᵤₜ)}/cos(θₒᵤₜ)|≦{0.553/(π·N·L)}(λ²/Δλ) (A)

(18) The dispersion compensation optical apparatus according to (17), in which

the following formula (B) is satisfied assuming that m is an integer and a refractive index modulation degree of the diffraction grating member is Δn.

{(0.8+2m)·λ/Δn}·{cos(θᵢₙ)·cos(θₒᵤₜ)}^{1/2}≦L≦{(1.2+2m)·λ/Δn}·{cos(θᵢₙ)·cos(θₒᵤₜ)}^{1/2} (B)

(19) (Semiconductor laser apparatus assembly: first mode)

A semiconductor laser apparatus assembly, including:

a mode synchronous semiconductor laser device; and

the dispersion compensation optical apparatus according to any one of (1) to (18) on which the laser light emitted from the mode synchronous semiconductor laser device is incident.

(20) (Semiconductor laser apparatus assembly: second mode)

A semiconductor laser apparatus assembly, including:

a mode synchronous semiconductor laser device;

a first dispersion compensation optical apparatus on which laser light emitted from the mode synchronous semiconductor laser device is incident;

a semiconductor light amplifier on which the laser light emitted from the first dispersion compensation optical apparatus is incident; and

a second dispersion compensation optical apparatus on which the laser light emitted from the semiconductor light amplifier is incident.

(21) The semiconductor laser apparatus assembly according to (20), in which

the first dispersion compensation optical apparatus includes the dispersion compensation optical apparatus according to any one of (1) to (18).

(22) The semiconductor laser apparatus assembly according to (20) or (21), in which

the second dispersion compensation optical apparatus includes the dispersion compensation optical apparatus according to any one of (1) to (10).

(23) The semiconductor laser apparatus assembly according to any one of (19) to (22), in which

the mode synchronous semiconductor laser device has a saturable absorption region.

(24) The semiconductor laser apparatus assembly according to (23), in which

the mode synchronous semiconductor laser device has a lamination structure in which a first compound semiconductor layer made of a GaN-based compound semiconductor and having a first conductive type, a third compound semiconductor layer made of the GaN-based compound semiconductor, and a second compound semiconductor layer made of the GaN-based compound semiconductor and having a second conductive type different from the first conductive type are successively laminated one on another.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A dispersion compensation optical apparatus, comprising:
a first transmission type volume hologram diffraction grating; and
a second transmission type volume hologram diffraction grating, wherein
the first and second transmission type volume hologram diffraction gratings are arranged facing each other, and
a sum of an incident angle of laser light and an emitting angle of first-order diffracted light is 90° in each of the first and second transmission type volume hologram diffraction gratings.

2. The dispersion compensation optical apparatus according to claim 1, wherein
the emitting angle of the first-order diffracted light is larger than the incident angle of the laser light in the first transmission type volume hologram diffraction grating on which the laser light emitted from a semiconductor laser device is incident.

3. A dispersion compensation optical apparatus, comprising:
a first transmission type volume hologram diffraction grating; and
a second transmission type volume hologram diffraction grating, wherein
the first and second transmission type volume hologram diffraction gratings are arranged facing each other, and
an incident angle of laser light and an emitting angle of first-order diffracted light are substantially equal in each of the first and second transmission type volume hologram diffraction gratings.

4. The dispersion compensation optical apparatus according to claim 3, wherein
a sum of the incident angle of the laser light and the emitting angle of the first-order diffracted light is 90°.

5. The dispersion compensation optical apparatus according to claim 1, wherein
the laser light is incident on the first transmission type volume hologram diffraction grating to be diffracted and emitted as the first-order diffracted light, and
the laser light is then incident on the second transmission type volume hologram diffraction grating to be diffracted and emitted to an outside of a system as the first-order diffracted light.

6. The dispersion compensation optical apparatus according to claim 5, further comprising:
a first reflection mirror; and
a second reflection mirror, wherein
the first and second reflection mirrors are arranged parallel to each other, and
the laser light emitted from the second transmission type volume hologram diffraction grating collides with the first reflection mirror to be reflected and then collides with the second reflection mirror to be reflected.

7. The dispersion compensation optical apparatus according to claim 6, wherein
the laser light reflected by the second reflection mirror is nearly positioned on an extended line of the laser light incident on the first transmission type volume hologram diffraction grating.

8. The dispersion compensation optical apparatus according to claim 5, further comprising:
a first reflection mirror; and
a second reflection mirror, wherein
the laser light emitted from the first transmission type volume hologram diffraction grating collides with the first reflection mirror to be reflected, and
the laser light then collides with the second reflection mirror to be reflected and is incident on the second transmission type volume hologram diffraction grating.

9. The dispersion compensation optical apparatus according to claim 1, wherein
the first transmission type volume hologram diffraction grating is provided on a first face of a substrate, and
the second transmission type volume hologram diffraction grating is provided on a second face of the substrate, the second face facing the first face.

10. The dispersion compensation optical apparatus according to claim 1, further comprising:
a reflection mirror, wherein
the laser light is incident on the first transmission type volume hologram diffraction grating to be diffracted and emitted as the first-order diffracted light,
the laser light is then incident on the second transmission type volume hologram diffraction grating to be diffracted and emitted as the first-order diffracted light to collide with the reflection mirror,
the laser light reflected by the reflection mirror is incident on the second transmission type volume hologram diffraction grating again to be diffracted and emitted as the first-order diffracted light, and
the laser light is incident on the first transmission type volume hologram diffraction grating again to be diffracted and emitted to an outside of a system.

11. The dispersion compensation optical apparatus according to claim 1, wherein
a group velocity dispersion value is changed with a change in a distance between the two transmission type volume hologram diffraction gratings.

12. A dispersion compensation optical apparatus, comprising:
a transmission type volume hologram diffraction grating; and
a reflection mirror, wherein
a sum of an incident angle of laser light and an emitting angle of first-order diffracted light is 90° or the incident angle of the laser light and the emitting angle of the first-order diffracted light are substantially equal in the transmission type volume hologram diffraction grating,
the laser light emitted from a semiconductor laser device is incident on the transmission type volume hologram diffraction grating to be diffracted and emitted as the first-order diffracted light to collide with the reflection mirror, and
the first-order diffracted light reflected by the reflection mirror is incident on the transmission type volume hologram diffraction grating again to be diffracted and emitted to an outside of a system.

13. The dispersion compensation optical apparatus according to claim 12, wherein
a group velocity dispersion value is changed with a change in a distance between the transmission type volume hologram diffraction grating and the reflection mirror.

14. The dispersion compensation optical apparatus according to claim 1, wherein
a semiconductor laser device from which the laser light is emitted includes a mode synchronous semiconductor laser device.

15. A semiconductor laser apparatus assembly, comprising:
a mode synchronous semiconductor laser device; and
the dispersion compensation optical apparatus according to claim 1 on which the laser light emitted from the mode synchronous semiconductor laser device is incident.

16. A semiconductor laser apparatus assembly, comprising:
a mode synchronous semiconductor laser device;
a first dispersion compensation optical apparatus on which laser light emitted from the mode synchronous semiconductor laser device is incident;
a semiconductor light amplifier on which the laser light emitted from the first dispersion compensation optical apparatus is incident; and
a second dispersion compensation optical apparatus on which the laser light emitted from the semiconductor light amplifier is incident.

17. The semiconductor laser apparatus assembly according to claim 16, wherein
the first dispersion compensation optical apparatus includes the dispersion compensation optical apparatus according to claim 1.

18. The semiconductor laser apparatus assembly according to claim 16, wherein
the second dispersion compensation optical apparatus includes the dispersion compensation optical apparatus according to claim 1.

19. The semiconductor laser apparatus assembly according to claim 15, wherein
the mode synchronous semiconductor laser device has a saturable absorption region.

20. The semiconductor laser apparatus assembly according to claim 19, wherein
the mode synchronous semiconductor laser device has a lamination structure in which a first compound semiconductor layer made of a GaN-based compound semiconductor and having a first conductive type, a third compound semiconductor layer made of the GaN-based compound semiconductor, and a second compound semiconductor layer made of the GaN-based compound semiconductor and having a second conductive type different from the first conductive type are successively laminated one on another.
